(19) United States
(12) Patent Application Publication
(10) Pub. No.: US 2013/0269181 A1
(43) Pub. Date: Oct. 17, 2013

(54) SYSTEM AND METHOD FOR MODULAR PHOTOVOLTAIC POWER

(71) Applicants: Troy McBride, Norwich, VT (US); Joel Stettenheim, Norwich, VT (US); Oliver Brambles, Lake Placid, NY (US); Scott Snyder, Hanover, NH (US)

(72) Inventors: Troy McBride, Norwich, VT (US); Joel Stettenheim, Norwich, VT (US); Oliver Brambles, Lake Placid, NY (US); Scott Snyder, Hanover, NH (US)

(73) Assignee: NORWICH TECHNOLOGIES, INC., Norwich, VT (US)

(21) Appl. No.: 13/857,938

(22) Filed: Apr. 5, 2013

Related U.S. Application Data
(60) Provisional application No. 61/620,978, filed on Apr. 5, 2012.

(51) Int. Cl. H01L 31/048

(52) U.S. Cl. CPC H01L 31/048; H01L 31/0482
USPC 29/825; 52/745.21

(57) ABSTRACT

A prefabricated array of photovoltaic modules mechanically assembled to a frame and pre-wired at an assembly location such as a factory and is transported to an installation location. The prefabricated array is wired so that a connection to a load, such as a home or an AC power delivery system can be accomplished by connecting a single connector to the load. The prefabricated array can be conveniently set up at the installation site using a lifting point attached to the array, for example at the frame. The time required to perform the installation and make the necessary electrical connections to make the array operable when illuminated can be as short as one hour.

### CROSS-REFERENCE TO RELATED APPLICATIONS

This application claims priority to and the benefit of co-pending U.S. provisional patent application Ser. No. 61/620,978, filed Apr. 5, 2012, which application is incorporated herein by reference in its entirety.

### FIELD OF THE INVENTION

The invention relates to photovoltaic solar power in general and particularly to a system that employs photovoltaic modules.

### BACKGROUND OF THE INVENTION

Photovoltaic (PV) panels enable electricity to be generated from sunlight. The scale of generation by a given PV installation depends on the total surface area of solar panels, the intrinsic efficiency of the panels, the fixed or varied orientation of the panels, insolation (sunlight actually reaching the panels) at the installation site and across the panel field, and intelligent control (if any) of electrical parameters of the panels and their connection to a load (e.g., grid or home). PV installations can be, and are, built across a continuum of sizes, from hand-held chargers, pole-mounted systems, domestic rooftop systems, and large-roof systems to multi-megawatt systems on dedicated acreage.

Above the handheld scale, most PV installations are custom: that is, they are engineered in a site-specific manner and require on-site, panel-by-panel assemblage by skilled installers and electricians. In many contexts (e.g., domestic rooftop PV), panels and other components are sized to be lifted by a single person. Wiring of an array of panels is done by hand and on-site.

Costs entailed by construction of a PV installation other than the costs for hardware (panels, inverters, cables, mounting hardware, etc.) are herein termed “soft costs.” Soft costs may be divided into four primary categories, i.e., (1) customer acquisition (e.g., marketing, site visits, bid preparation, followup), (2) financing and contracting (e.g., cost of capital, insurance), (3) permitting, inspection, and interconnection, and (4) installation and performance (e.g., installation labor, operations and maintenance, sub-optimal system performance).

Soft costs can make up to ˜50% of the cost of a PV installation (e.g., typically, for residential rooftop systems, they are approximately a third of total system cost). They are increased by customized design and installation. For example, site-specific design and engineering of a PV installation alone can absorb ˜15% of cost. Moreover, for residential rooftop PV, cycle time from initial customer commitment to system turn-on averages six weeks; installation of a typical residential system requires on the order of three days of on-site skilled labor; and additional costs are incurred for repairs of defects incurred during such assembly. While hardware costs (e.g., solar panel levelized cost of energy) have been declining steadily for many years and are widely expected to continue doing so, soft costs have proved relatively stable.

There is thus a need for innovative methods and systems for the design and delivery of non-customized or minimally customized PV installations that reduce soft costs. Such novel methods and systems should be capable of exploiting ongoing technical advances in solar panel fabrication, panel efficiency, mounting hardware, electronic optimization of panel performance, and the like, but should not be dependent on such advances.

### SUMMARY OF THE INVENTION

The invention pertains to a system and method for the production of prefabricated, modular photovoltaic power systems that are assembled off-site (e.g., in a factory), transported in an approximately finished state to a site, and installed at the site with minimal effort. This approach provides as benefits reduced installation time and cost and increased system reliability.

According to one aspect, the invention features a framework (or frame) on which one or more solar panels (or photovoltaic modules each comprising a plurality of solar cells) are mounted to form a modular PV field or array. The modular field or array, herein also termed the meta-module is shaped and sized for a specific application: e.g., for domestic rooftop installations, a meta-module may be a rectangle of 2.6 by 5.8 meters and may have a generating capacity of approximately 2.4 kilowatts (kW). The framework is sufficiently light and strong to permit its transfer by machinery, e.g., forklift or crane, without undergoing unacceptable bowing, twisting, or other damage, and may be provided with connection points or lifting points (e.g., slots, ringbolts, strapping points) to facilitate such movement. The meta-module may comprise wiring that connects the meta-module's solar panels to each other in series, in parallel or in a combination of series and parallel connections, and/or to one or more electronic devices (e.g., micro-inverters, string inverters, optimizers) for the electrical conditioning of the output of the solar panels, and/or to one or more common buses that terminate in one or more standardized, plug-ready electrical connectors (herein also termed “quick connects”), preferably at a point or points on the edge of the meta-module. The meta-module may also comprise devices for sensing and transmitting measurements (e.g., of voltage, current, temperature) from various parts of the meta-module, and for enabling signals from an external controller to modify the electrical properties of various components comprised by the meta-module. The meta-module may comprise arrangements (e.g., pockets, frames) for the reception of anchoring weights (e.g., cinderblocks) and/or various anchoring connectors (e.g., nails, screws, hooks, clamps) to secure the module in its final site position against forces caused by gravity, snow loads, wind, and the like.

In one embodiment, the meta-module is designed for full factory assembly (except for a final connection to load, e.g., utility grid connection) using standard components and can be dropped into place (e.g., onto a residential rooftop) using a conventional boom truck. Preferably, the meta-module is of dimensions allowing standard truck transport (e.g., minimum dimension equals to or less than 8.5 feet). Weights may be employed to stabilize the meta-module rather than roof-penetrating hardware (e.g., screws). Connections to internal house wiring may be omitted from the meta-module in favor of direct, standardized connection to a local utility grid. Thus, the meta-module may be dropped into place by machinery, attached or weighted for stability, and wired to local loads or a grid via one or a few wiring assemblies equipped at the site of manufacture with standard connectors. Custom design work is eliminated, and the quantity of custom, on-site assembly work involved is small as compared to the prior art. In some embodiments, the design of the meta-module is configured to allow its ready transport by trucking carrier freight.

By its modular, prefabricated nature, the meta-module standardizes a number of soft costs (e.g., marketing, paperwork, and pricing) and thus reduces costs relating to site-specific design, engineering, and bid preparation. Standardization of design and manufacture, with rapid modular installation (e.g., drop-in using boom crane), reduces labor costs, with labor reduced from ˜3 days for installation according to the prior art to minutes for drop-in with a few hours for utility interconnection (also shortened dramatically by standardization): all told, approximately 4 hours or less from crew arrival to crew departure. Standardization also shrinks cycle time (customer contact to system finalization) from, e.g., approximately 6 weeks according to the prior art to approximately 6 or fewer days. Short cycle time reduces follow-up and other wait-time costs. In various embodiments, the drop-in, pre-inspected meta-module system virtually eliminates wait time and idle crews. These efficiency improvements readily support an approximately fourfold reduction in permitting, inspection, and interconnection costs from a prior-art value of approximately $0.40 per watt of installed capacity ($0.40/W) to approximately $0.10/W.

Current installations of PV systems require extensive specialized wiring that is unique to each location, typically with both interior and exterior connections, often in cramped or difficult-to-access locations such as attics and crawlspaces. The associated costs of such wiring are significant, as all the work must be done by professional electricians. Inclement weather can further extend the total time needed to complete an installation. Moreover, in the prior art, hardware placement and panel wiring are typically done on rooftops under challenging conditions, heightening the risk of injury and technical errors (e.g., pinched wires, poorly formed connections). An Energy Safe Victoria (Australia) audit of ˜100 homes with PV installations found installation quality issues in over 30% of systems. Standardization of design and manufacture also reduces defect rates significantly, according to standard principles of industrialization: factory assembly reduces sub-optimal system performance and service needs by up to twenty-fold. Thus, error rates in various embodiments of the invention will be lower than in systems assembled under awkward rooftop conditions, and reduction of hazard to workers should reduce insurance and worker-compensation costs. In addition, assembly in a factory can be performed without regard to the time of day or the outside weather conditions. Further in some embodiments, the factory assembly is configured to minimize a cost and or a fabrication time associated with building the meta-module.

Together, these and other benefits realizable by various embodiments of the invention readily support a six-fold reduction in installation and performance costs from approximately $0.60/W to approximately $0.10/W.

Lowering barriers to customer commitment such as high transaction complexity will lower sales and marketing costs associated with nonproductive site visits and sales calls. Since a drop-in system is also a lift-off system, in one embodiment a money-back guarantee may be offered to buyers of the meta-module, increasing the likelihood of customer commitment and thus reducing soft costs associated with phantom orders and cancellations. Analysis of satellite imagery (e.g., using supervised software tools) may be used to identify sites (e.g., domestic rooftops) suitable for the standardized meta-module. Moreover, the lift-off nature of the meta-module minimizes unrecoverable sunk costs in the event of customer default, with likely lessened insurance costs due to lessened seller risk.

The meta-module does not rely on any specific PV or balance-of-system technologies. Its advantages over the prior art rest on standardization, simplified installation, and lowering of complexity barriers to buyer commitment. The meta-module comprises standard solar panels, microinverters, meters, framework materials, and other components: however, advances made by PV-panel and balance-of-systems manufacturers can be incorporated into the meta-module and will further lower its installed cost. By means of an electrical quick connect, the meta-module may be connected to a pre-wired solar interconnection box, supplied with the meta-module, containing all necessary disconnects, fuses, a solar meter (i.e., device for measuring the summed electrical energy output of a photovoltaic generator over a period of time, and possibly other characteristics of the electrical output of the photovoltaic generator), and other components; the solar interconnection box, in turn, may be connected to a utility grid or site-specific load or microgrid by a qualified electrician.

In another embodiment, a plurality of meta-modules may be connected to form an array of meta-modules. Electrical quick connects permit the chaining of meta-modules to form the array of meta-module: the same quick connect permits the connection of one of the modules in the meta-module to a pre-wired solar interconnection box, which may in turn be connected to a utility grid, a site-specific load or a microgrid. In this manner, a large solar field array (e.g. 10 kW, 100 kW, 1000 kW or larger) may be installed in a short time period and inexpensively. In one such embodiment, the installation includes an extended installation rack to which multiple meta-modules can be quickly and easily connected. In one such embodiment, the installation rack can include extendable mounting legs enabling the rapid placement and securing of the installation rack. In one such embodiment, the installation rack is prefabricated in a factory setting and configured for low cost and ease of installation. In one embodiment, the meta-module is installed on a flat roof and is attached to a installation rack that provides a secure base and proper orientation. In one embodiment, the installation rack for a roof installation or a ground installation is integrated with the meta-module and the array of PV modules and mounting structure is installed as a single entity.

In various embodiments, manufacture and installation of the module comprises the following steps:

A) Manufacturing and Transport
1) Attach solar panels to frame. Frame includes coupling mechanism for attachment to anchors at final installation site.
2) Form electrical connections between solar panels, wiring, and any electronic components comprised by the meta-module (micro-inverter(s), optimizers, etc.).
3) Attach wiring for connection to solar meter and/or house service
4) Transport pre-assembled, pre-wired meta-module to installation site

B) Installation
1) Install site anchors, if required, anchoring meta-module to roof, pole, or other base structure at installation site. Site anchors may include a system of “load bars” attached to anchoring hardware (weights, roof mounts), to which the meta-module may be attached upon placement.
2) Transfer meta-module to site (e.g., lift in place with boom truck)
3) Secure meta-module to installation site anchors. For example, in various embodiments, two parallel load bars may be attached to a rooftop using anchoring hardware, with space between the bars for a meta-module, and the meta-module may then be attached to one of the load bars by carabiners and to the other by turnbuckles. Tightening the turnbuckles then secures the meta-module to the load bars. A runner or spacer (e.g., of plastic) may be placed under the meta-module to distribute some of the meta-module's weight directly over a site surface (e.g., roof), preventing bowing of the meta-module under its own weight or snow loads.
4) Connect meta-module wiring directly to solar meter or house meter box

In embodiments in which a plurality of meta-modules are connected for form an array of meta-modules, manufacture and installation are similar except that installation comprises the interconnection of individual meta-modules to form the array of meta-modules.

In various other embodiments, a pole mount is prepared to receive the meta-module. The pole mount may consist of one or more central upright members, an adjustable swivel head, a base mount (e.g., planar framework or plate), and an electrical quick connect; wiring is run from the base of the pole (e.g., in a trench or conduit) to a suitable interconnect point (e.g., solar meter). In various such embodiments, installation of the meta-module entails connection of the meta-module framework to the base mount by means of a standardized quick-mount mechanism. Herein, a “quick-mount mechanism” is any mechanical coupling device that enables at least two objects to be securely and permanently attached with relative rapidity by hand with the use of simple tools or no tools.

In one embodiment, an electrical connector for the meta-module is configured so that respective electrical power output terminals provide a disconnectable connection to another electrical apparatus, where the other electrical apparatus is a solar meter located at an installation location.

In one embodiment, an electrical connector for the meta-module is configured so that respective electrical power output terminals provide a disconnectable connection to another electrical apparatus, where the other electrical apparatus is another prefabricated array of photovoltaic modules.

In one embodiment, an electrical connector for the meta-module is configured so that respective electrical power output terminals provide a disconnectable connection to another electrical apparatus, where the other electrical apparatus is a power inverter.

In one embodiment, an electrical connector for the meta-module is configured so that respective electrical power output terminals provide a disconnectable connection to another electrical apparatus, where the other electrical apparatus is a utility electrical service box at the second location.

In an embodiment, the meta-module is larger in size or heavier than can be reasonably manually carried by a single worker and requires a lifting mechanism to install.

As will be recognized, the invention is directed to systems and methods that minimize the time and effort in preparing and installing a photovoltaic system at an installation location, and is intended to provide photovoltaic systems that have improved reliability. In order to do so optimally, it is advantageous to prepare the system as one or more prefabricated segments, such as a prefabricated array of photovoltaic modules and a second prefabricated assembly that contains all of the power conditioning, power control and power metering apparatus that is needed to connect the prefabricated array of photovoltaic modules to a facility such as a home, or to the AC power grid so that the generated electricity can be useful to a user. In one example, the prefabricated array of photovoltaic modules and the second prefabricated assembly are preassembled, connected and tested at a factory so as to eliminate the possibility that a faulty system will be transported to an installation location and only discovered to have problems when it is installed. After passing operational tests at the factory, which optionally may be performed out of doors, or indoors using artificial illumination rather than sunlight, the two prefabricated components are disconnected, brought to the installation location, and installed at that location.

According to one aspect, the invention features a prefabricated array of photovoltaic modules (or “meta-module”). The prefabricated array of photovoltaic modules comprises a frame configured to support a plurality of photovoltaic modules, the frame having an electrical ground terminal, a first electrical power terminal and a second electrical power terminal; the plurality of photovoltaic modules mechanically connected to the frame, each of the plurality of photovoltaic modules comprising one or more photovoltaic solar cells, each of the plurality of photovoltaic modules configured to generate at least 10 Watts of electrical power under an illumination level of 1 kiloWatt per square meter, the plurality of photovoltaic modules each having a ground terminal in electrical contact with the ground terminal of the frame, a first electrical power terminal in electrical contact with the first electrical power terminal of the frame, and a second electrical power terminal in electrical contact with the second electrical power terminal of the frame; and an electrical connector mechanically connected to the frame and configured to provide a connection of the electrical ground terminal of the frame, the first electrical power terminal of the frame, and the second electrical power terminal of the frame to another electrical apparatus; the prefabricated array of photovoltaic modules configured to be transported from a first location and installed at a second location with an electrical connection to the prefabricated array of photovoltaic modules to be made at the second location by way of the electrical connector.

In one embodiment, the frame has an attachment point, the attachment point configured to provide a secure mechanical attachment of the prefabricated array of photovoltaic modules when installed at the second location.

In another embodiment, the secure mechanical attachment of the prefabricated array of photovoltaic modules when installed at the second location is configured to be readily detachable.

In yet another embodiment, the frame has a lifting point, the lifting point configured to allow the prefabricated array of photovoltaic modules to be lifted by a mechanical lifting apparatus.

In still another embodiment, the prefabricated array of photovoltaic modules further comprises a mechanical counterweight configured to counterbalance a mass of the prefabricated array of photovoltaic modules.

In a further embodiment, the prefabricated array of photovoltaic modules is configured to be installed at a ridge of a peaked roof.

In yet a further embodiment, the prefabricated array of photovoltaic modules further comprises a removable exoskeleton configured to stabilize the prefabricated array of photovoltaic modules during a time when the prefabricated array of photovoltaic modules is moved to the second location. The prefabricated array of photovoltaic modules of claim 1, further comprising a removable exoskeleton configured to stabilize the prefabricated array of photovoltaic modules during a time when the prefabricated array of photovoltaic modules is moved to the second location.

In an additional embodiment, the prefabricated array of photovoltaic modules is configured to provide 1 kiloWatt or more of electrical power under an illumination level of 1 kiloWatt per square meter.

In one more embodiment, an illuminable area of the prefabricated array of photovoltaic modules is at least 64 square feet.

In still a further embodiment, the prefabricated array of photovoltaic modules includes a power inverter integrated with the prefabricated array of photovoltaic modules, and the power inverter has an electrical connector configured to provide a connection of electrical output terminals of the power inverter to an AC electrical system.

In one embodiment, each of the prefabricated array of photovoltaic modules includes a power inverter integrated therewith, and the each of the respective power inverters has an electrical connector configured to provide a connection of electrical output terminals to an AC electrical system.

In another embodiment, the electrical connector is configured so that the respective electrical power output terminals provide a disconnectable connection to another electrical apparatus.

In yet another embodiment, at least one module of the plurality of photovoltaic modules has at least one of a ground terminal in electrical contact with the ground terminal of the frame by way of a ground terminal of a second module of the plurality of photovoltaic modules, a first electrical power terminal in electrical contact with the first electrical power terminal of the frame by way of a first electrical power terminal of the second module of the plurality of photovoltaic modules, and a second electrical power terminal in electrical contact with the second electrical power terminal of the frame by way of a second electrical power terminal of the second module of the plurality of photovoltaic modules.

In still another embodiment, at least one module of the plurality of photovoltaic modules has at least one of a ground terminal in electrical contact with the ground terminal of the frame by way of an electrical connection provided by a first intermediate electrical device, a first electrical power terminal in electrical contact with the first electrical power terminal of the frame by way of an electrical connection provided by a second intermediate electrical device, and a second electrical power terminal in electrical contact with the second electrical power terminal of the frame by way of an electrical connection provided by a third intermediate electrical device.

In a further embodiment, at least two of the first intermediate electrical device, the second intermediate electrical device, and the third intermediate electrical device are the same.

In a further embodiment, at least one of the first intermediate electrical device, the second intermediate electrical device, and the third intermediate electrical device is chosen from the group consisting of an inverter and an optimizer.

In yet a further embodiment, the another electrical apparatus is a solar meter located at the second location.

In an additional embodiment, the another electrical apparatus is another prefabricated array of photovoltaic modules.

In one more embodiment, the another electrical apparatus is a power inverter.

In still a further embodiment, the another electrical apparatus is a utility electrical service box at the second location.

In another embodiment, the electrical connection includes connecting to a prefabricated solar interconnection box including at least one of a disconnect, an inverter, a meter, breakers, monitoring hardware and software, the prefabricated solar interconnection box being factory assembled.

In another embodiment, the prefabricated solar interconnection box is electrically attached to a utility power connection through a meter box, the connection being made without entering a structure at the second location.

In another embodiment, the prefabricated solar interconnection box includes an electrical connection to a utility meter box through a pass through adaptor configured to fit between a meter socket and a meter and to provide a readily formed electrical socket connection for connecting electrically in parallel to a non-utility side of the meter socket.

In another embodiment, the frame is sufficiently rigid that each of the array of photovoltaic modules remains intact while being transported from the first location and installed at the second location.

In another embodiment, the frame is connected by a mechanical quick connection to a load bar, the load bar installed by a worker and having a movable mounting bracket configured to allow for different attachment point spacing.

In another embodiment, at least one module of the plurality of photovoltaic modules has at least one of a first electrical power terminal in electrical contact with the first electrical power terminal of the frame by way of a first electrical power terminal of the second module of the plurality of photovoltaic modules, and a second electrical power terminal in electrical contact with the second electrical power terminal of the frame by way of a second electrical power terminal of the second module of the plurality of photovoltaic modules.

According to another aspect, the invention relates to a method of making a prefabricated array of photovoltaic modules. The method comprises the steps of: at a location different from a location of installation of the prefabricated array of photovoltaic modules: providing a frame configured to support a plurality of photovoltaic modules, the frame having an electrical ground terminal, a first electrical power terminal and a second electrical power terminal; providing the plurality of photovoltaic modules each comprises one or more photovoltaic solar cells, each of the plurality of photovoltaic modules configured to generate at least 10 Watts of electrical power under an illumination level of 1 kiloWatt per square meter, the plurality of photovoltaic modules each having a ground terminal, a first electrical power terminal, and a second electrical power terminal; providing an electrical connector configured to provide a connection of the electrical ground terminal of the frame, the first electrical power terminal of the frame, and the second electrical power terminal of the frame to respective electrical power terminals; and performing in any order the following activities: mechanically connecting the frame, the plurality of photovoltaic modules, and the electrical connector; electrically connecting the ground terminal of the frame to the ground terminal of the connector and to each of the respective ground terminals of the plurality of photovoltaic modules; electrically connecting the first electrical power terminal of the frame to the first electrical power terminal of the connector and to the respective first electrical power terminal of each of the plurality of photovoltaic modules; and electrically connecting the second electrical power terminal of the frame to the second electrical power terminal of the connector and to the respective second electrical power terminal of each of the plurality of photovoltaic modules; thereby making a prefabricated array of photovoltaic modules at a location different from a location of installation of the prefabricated array of photovoltaic modules.

In one embodiment, the location different from a location of installation of the prefabricated array of photovoltaic modules is a factory.

In another embodiment, the factory is configured to operate irrespective of time of day and irrespective of weather conditions.

In yet another embodiment, the factory is configured to minimize at least one of a time of manufacture, a fabrication error rate, and a cost of manufacture.

In still another embodiment, the frame further comprises an attachment point configured to provide a secure mechanical attachment of the prefabricated array of photovoltaic modules when installed at the location of installation.

In a further embodiment, a secure mechanical attachment point on the location of installation is configured to be readily detachable.

In yet a further embodiment, the frame further comprises a lifting point configured to allow the prefabricated array of photovoltaic modules to be lifted by a mechanical lifting apparatus.

In an additional embodiment, the frame further comprises a mechanical counterweight configured to counterbalance a mass of the prefabricated array of photovoltaic modules.

In one more embodiment, the prefabricated array of photovoltaic modules is installed at a ridge of a peaked roof.

In still a further embodiment, the frame further comprises a removable exoskeleton configured to stabilize the prefabricated array of photovoltaic modules during a time when the prefabricated array of photovoltaic modules is moved to the installation location.

In one embodiment, the prefabricated array of photovoltaic modules is configured to provide 1 kiloWatt or more of electrical power under an illumination level of 1 kiloWatt per square meter.

In another embodiment, an illuminable area of the prefabricated array of photovoltaic modules is at least 64 square feet.

In yet another embodiment, the method, further comprises the steps of: providing a power inverter having a ground input terminal, a first electrical power input terminal, and a second electrical power input terminal, and having an electrical connector configured to provide a connection of electrical output terminals of the power inverter to an AC electrical system; and performing in any order the following activities: mechanically connecting the power inverter to the frame; electrically connecting the ground terminal of the frame to the ground input terminal of the power inverter; electrically connecting the first electrical power terminal of the frame to the first electrical power input terminal of the power inverter; and electrically connecting the second electrical power terminal of the frame to the second electrical power input terminal of the power inverter.

In still another embodiment, all of the plurality of photovoltaic modules are electrically connected in parallel.

In a further embodiment, all of the plurality of photovoltaic modules are electrically connected in series.

In yet a further embodiment, some of the plurality of photovoltaic modules are electrically connected in parallel with others of the plurality of photovoltaic modules and some of the plurality of photovoltaic modules are electrically connected in series with others of the plurality of photovoltaic modules.

In another embodiment, the frame is sufficiently rigid that each of the array of photovoltaic modules remains intact while being transported to and installed at the installation location.

In another embodiment, the frame is connected by a mechanical quick connection to a load bar, the load bar installed by a worker and having a movable mounting bracket configured to allow for different attachment point spacing.

According to yet another aspect, the invention features a method of installing a prefabricated array of photovoltaic modules. The method comprises the steps of: providing at an installation location a prefabricated array of photovoltaic modules, the prefabricated array of photovoltaic modules having a frame with a plurality of photovoltaic modules mechanically connected to the frame, each of the plurality of photovoltaic modules comprising one or more photovoltaic solar cells, each of the plurality of photovoltaic modules configured to generate at least 50 Watts of electrical power under an illumination level of 1 kiloWatt per square meter, the prefabricated array of photovoltaic modules having an electrical connector mechanically connected to the frame and configured to provide electrical power output terminals, the prefabricated array of photovoltaic modules configured to be transported from a first location different from the installation location, with an electrical connection to the prefabricated array of photovoltaic modules to be made at the installation location by way of the electrical connector; disposing the prefabricated array of photovoltaic modules in a working orientation at the installation location; and making an electrical connection between the prefabricated array of photovoltaic modules and an electrical load by way of the electrical connector, thereby making the prefabricated array of photovoltaic modules electrically operational when the prefabricated array of photovoltaic modules is illuminated.

In one embodiment, the steps of disposing the prefabricated array of photovoltaic modules in a working orientation and making an electrical connection between the prefabricated array of photovoltaic modules and an electrical load by way of the electrical connector so as to make the prefabricated array of photovoltaic modules electrically operational when the prefabricated array of photovoltaic modules is illuminated are completed in a period of eight hours or less, measured from a time when the prefabricated array of photovoltaic modules first arrives at the installation location.

In another embodiment, the period is four hours or less, measured from a time when the prefabricated array of photovoltaic modules first arrives at the installation location.

In yet another embodiment, the period is two hours or less, measured from a time when the prefabricated array of photovoltaic modules first arrives at the installation location.

In still another embodiment, the period is one hour or less, measured from a time when the prefabricated array of photovoltaic modules first arrives at the installation location.

In a further embodiment, the method further comprises the step of lifting the prefabricated array of photovoltaic modules by way of a lifting point mechanically connected to the frame.

In yet a further embodiment, the lifting point mechanically connected to the frame is configured to allow the prefabricated array of photovoltaic modules to be lifted by a mechanical lifting apparatus.

In yet a further embodiment, the method of installing a prefabricated array of photovoltaic modules the prefabricated array of photovoltaic modules is brought to the installation location by a transport mechanism that includes the mechanical lifting apparatus.

In an additional embodiment, the method further comprises the step of securely attaching the prefabricated array of photovoltaic modules to the installation location using an attachment point mechanically connected to the frame.

In one more embodiment, the attachment point mechanically connected to the frame is mechanically connected to a corresponding attachment point installed at the installation location.

In still a further embodiment, the attachment point mechanically connected to the frame is mechanically connected to the corresponding attachment point in a readily detachable fashion.

In one embodiment, the method further comprises the step of installing an inverter between the prefabricated array of photovoltaic modules and the electrical load.

In another embodiment, the prefabricated array of photovoltaic modules further comprises a mechanical counterweight configured to counterbalance a mass of the prefabricated array of photovoltaic modules.

In yet another embodiment, the prefabricated array of photovoltaic modules is installed at a ridge of a peaked roof.

In still another embodiment, the prefabricated array of photovoltaic modules further comprises a removable exoskeleton configured to stabilize the prefabricated array of photovoltaic modules during a time when the prefabricated array of photovoltaic modules is moved to the installation location.

In a further embodiment, the prefabricated array of photovoltaic modules is configured to provide 1 kiloWatt or more of electrical power under an illumination level of 1 kiloWatt per square meter.

In yet a further embodiment, an illuminable area of the prefabricated array of photovoltaic modules is at least 64 square feet.

In an additional embodiment, at least one module of the plurality of photovoltaic modules has at least one of a ground terminal in electrical contact with the ground terminal of the frame by way of a ground terminal of a second module of the plurality of photovoltaic modules, a first electrical power terminal in electrical contact with the first electrical power terminal of the frame by way of a first electrical power terminal of a second module of the plurality of photovoltaic modules, and a second electrical power terminal in electrical contact with the second electrical power terminal of the frame by way of a second electrical power terminal of a second module of the plurality of photovoltaic modules.

In one more embodiment, at least one module of the plurality of photovoltaic modules has at least one of a ground terminal in electrical contact with the ground terminal of the frame by way of an electrical connection provided by a first intermediate electrical device, a first electrical power terminal in electrical contact with the first electrical power terminal of the frame by way of an electrical connection provided by a second intermediate electrical device, and a second electrical power terminal in electrical contact with the second electrical power terminal of the frame by way of an electrical connection provided by a third intermediate electrical device.

In still a further embodiment, at least two of the first intermediate electrical device, the second intermediate electrical device, and the third intermediate electrical device are the same.

In one embodiment, the prefabricated array of photovoltaic modules includes a power inverter integrated with the prefabricated array of photovoltaic modules.

In another embodiment, each of the prefabricated array of photovoltaic modules includes a power inverter integrated therewith.

In yet another embodiment, the electrical connector is a disconnectable connector.

In still another embodiment, the electrical load includes a solar meter located at the installation location.

In a further embodiment, the electrical load is another prefabricated array of photovoltaic modules.

In yet a further embodiment, the electrical load includes a power inverter.

In still a further embodiment, the electrical load includes a utility electrical service box at the installation location.

In yet a further embodiment, the electrical load includes a prefabricated solar interconnection box including at least one of a disconnect, an inverter, a meter, breakers, monitoring hardware and software, the prefabricated solar interconnection box being factory assembled.

In yet a further embodiment, the prefabricated solar interconnection box has an electrical quick-connect for connection to the electrical connection.

In still another embodiment, the prefabricated solar interconnection box is electrically attached to a utility power connection through a meter box, the connection being made without entering a structure at the installation location.

In another embodiment, the prefabricated solar interconnection box includes an electrical connection to a utility meter box through a pass through adaptor that fits between a meter socket and a meter and provides a readily formed electrical socket connection for connecting electrically in parallel to a non-utility side of the meter socket.

In another embodiment, disposing the prefabricated array of photovoltaic modules in a working orientation includes use of a sling.

In another embodiment, the frame is sufficiently rigid that each of the array of photovoltaic modules remains intact during the disposing the prefabricated array of photovoltaic modules in a working orientation.

In another embodiment, the frame is connected by a mechanical quick connection to a load bar, the load bar installed by a worker and having a movable mounting bracket configured to allow for different attachment point spacing.

In another embodiment at least one module of the plurality of photovoltaic modules has at least one of a first electrical power terminal in electrical contact with the first electrical power terminal of the frame by way of a first electrical power terminal of the second module of the plurality of photovoltaic modules, and a second electrical power terminal in electrical contact with the second electrical power terminal of the frame by way of a second electrical power terminal of the second module of the plurality of photovoltaic modules.

According to another aspect, the invention features a method of removing a prefabricated array of photovoltaic modules installed at an installation location. The method comprises the steps of: starting with a prefabricated array of photovoltaic modules installed at an installation location, the prefabricated array of photovoltaic modules having a frame with a plurality of photovoltaic modules mechanically connected to the frame, each of the plurality of photovoltaic modules comprising one or more photovoltaic solar cells, each of the plurality of photovoltaic modules configured to generate at least 50 Watts of electrical power under an illumination level of 1 kiloWatt per square meter, and having an electrical connector mechanically connected to the frame and configured to provide electrical power output terminals, with the only electrical connection between the prefabricated array of photovoltaic modules and an electrical load being made by way of the electrical connector; performing in any order the next two steps: disconnecting any mechanical connection between the prefabricated array of photovoltaic modules and the installation location; and breaking the electrical connection between the prefabricated array of photovoltaic modules and the electrical load; and removing the prefabricated array of photovoltaic modules from the installation location.

In one embodiment, the steps of disconnecting any mechanical connection between the prefabricated array of photovoltaic modules and the installation location, breaking the electrical connection between the prefabricated array of photovoltaic modules and an electrical load by way of the electrical connector, and removing the prefabricated array of photovoltaic modules from the installation location are completed in a period of eight hours or less, measured from a time when the first of the steps of disconnecting any mechanical connection and breaking the electrical connection is initiated.

In another embodiment, the period is four hours or less, measured from a time when the first of the steps of disconnecting any mechanical connection and breaking the electrical connection is initiated.

In yet another embodiment, the period is two hours or less, measured from a time when the first of the steps of disconnecting any mechanical connection and breaking the electrical connection is initiated.

In still another embodiment, the period is one hour or less, measured from a time when the first of the steps of disconnecting any mechanical connection and breaking the electrical connection is initiated.

In a further embodiment, the step of breaking the electrical connection between the prefabricated array of photovoltaic modules and the electrical load is accomplished by disconnecting the electrical connector.

In yet a further embodiment, the step of removing the prefabricated array of photovoltaic modules from the installation location involves lifting the prefabricated array of photovoltaic modules by way of a lifting point mechanically connected to the frame.

In an additional embodiment, the step of removing the prefabricated array of photovoltaic modules from the installation location involves lifting using a mechanical lifting apparatus.

In one more embodiment, the step of disconnecting any mechanical connection between the prefabricated array of photovoltaic modules and the installation location involves disconnecting a connection between a first attachment point mechanically connected to the frame and a second attachment point removably installed at the installation location.

In still a further embodiment, the method further comprises the step of removing the second attachment point removably installed at the installation location.

In one embodiment, the method further comprises the step of removing an inverter.

In another embodiment, the prefabricated array of photovoltaic modules further comprises a mechanical counterweight configured to counterbalance a mass of the prefabricated array of photovoltaic modules when the prefabricated array of photovoltaic modules is installed at a ridge of a peaked roof.

In yet another embodiment, the prefabricated array of photovoltaic modules further comprises a removable exoskeleton configured to stabilize the prefabricated array of photovoltaic modules during a time when the prefabricated array of photovoltaic modules is removed from the installation location.

In still another embodiment, the prefabricated array of photovoltaic modules is configured to provide 1 kiloWatt or more of electrical power under an illumination level of 1 kiloWatt per square meter.

In a further embodiment, at least one module of the plurality of photovoltaic modules has at least one of a ground terminal in electrical contact with a ground terminal of the frame by way of a ground terminal of a second module of the plurality of photovoltaic modules, a first electrical power terminal in electrical contact with a first electrical power terminal of the frame by way of a first electrical power terminal of a second module of the plurality of photovoltaic modules, and a second electrical power terminal in electrical contact with a second electrical power terminal of the frame by way of a second electrical power terminal of a second module of the plurality of photovoltaic modules.

In yet a further embodiment, an illuminable area of the prefabricated array of photovoltaic modules is at least 64 square feet.

In an additional embodiment, the prefabricated array of photovoltaic modules includes a power inverter integrated with the prefabricated array of photovoltaic modules.

In one more embodiment, each module of the prefabricated array of photovoltaic modules includes a power inverter integrated therewith.

These and other objects, along with the advantages and features of the present invention herein disclosed, will become apparent through reference to the following description, the accompanying drawings, and the claims. Furthermore, it is to be understood that the features of the various embodiments described herein are not mutually exclusive and may exist in various combinations and permutations.

### BRIEF DESCRIPTION OF THE DRAWINGS

The objects and features of the invention can be better understood with reference to the drawings described below, and the claims. The drawings are not necessarily to scale, emphasis instead generally being placed upon illustrating the principles of the invention. In the drawings, like numerals are used to indicate like parts throughout the various views.

FIG. 1 illustrates an exemplary grid-connected photovoltaic installation according to the prior art.

FIG. 2 illustrates the steps of a prior art method for completed customer acquisition of a residential photovoltaic installation.

FIG. 3 illustrates an exemplary grid-connected photovoltaic installation according to an embodiment of the invention.

FIG. 4 illustrates an exemplary grid-connected photovoltaic installation.

FIG. 5 illustrates a method for emplacement of a photovoltaic installation.

FIG. 6 illustrates the structure of an exemplary grid-connected photovoltaic installation.

FIG. 7 illustrates the structure of an exemplary grid-connected photovoltaic installation.

FIG. 8 illustrates the structure of an exemplary grid-connected photovoltaic installation.

FIG. 9 illustrates the structure of an exemplary grid-connected photovoltaic installation.

FIG. 10 illustrates the structure of an exemplary grid-connected photovoltaic installation.

FIG. 11A illustrates a method for emplacement of exemplary grid-connected photovoltaic installation.

FIG. 11B illustrates a method for emplacement of exemplary grid-connected photovoltaic installation.

FIG. 11C illustrates a method for enabling workers to install an exemplary grid-connected photovoltaic installation.

FIG. 11D illustrates a method for enabling workers to install an exemplary grid-connected photovoltaic installation.

FIG. 12A illustrates the attachment of solar panels to a framework.

FIG. 12B illustrates the structure of a lift frame for lifting solar panels attached to a framework.

FIG. 12C illustrates the relationship of a lift frame to a solar-panel framework assembly before attachment.

FIG. 12D illustrates the relationship of a lift frame to a solar-panel framework assembly after attachment.

FIG. 12E illustrates the relationship of a lift frame to a solar-panel framework assembly after attachment.

FIG. 13 illustrates the steps of a method of assembly of a modular prefabricated photovoltaic array according to aspects of the invention.

FIG. 14 illustrates the steps of a method of installation of a modular prefabricated photovoltaic array according to aspects of the invention.

FIG. 15A illustrates the attachment of a photovoltaic meta-module to mounting hardware.

FIG. 15B illustrates the attachment of a photovoltaic meta-module to mounting hardware.

FIG. 16 illustrates mounting hardware that exerts an anchoring pull on a photovoltaic meta-module.

FIG. 16B illustrates mounting hardware that attaches a photovoltaic meta-module directly to a surface.

FIG. 17A illustrates the anchoring of a photovoltaic meta-module on a flat surface using a ballast frame.

FIG. 17B illustrates the anchoring of a photovoltaic meta-module at an angle on a flat surface using a ballast frame.

FIG. 17C illustrates some of the hardware used to anchor a photovoltaic meta-module at an angle on a flat surface using a ballast frame.

FIG. 18A illustrates a system in which multiple photovoltaic meta-modules are anchored using ballast frames.

FIG. 18B illustrates a system in which multiple photovoltaic meta-modules are anchored using ballast frames.

FIG. 19 illustrates a system in which multiple photovoltaic meta-modules are anchored at an angle using ballast frames.

FIG. 20 illustrates a system in which multiple photovoltaic meta-modules are anchored using ballast frames.

FIG. 21 illustrates a system in which a photovoltaic meta-module is anchored directly to a surface.

FIG. 22 illustrates photovoltaic meta-modules attached to a base frame suitable for pole mounting.

FIG. 23 illustrates photovoltaic meta-modules on a base frame mounted on a pole.

FIG. 24A illustrates photovoltaic meta-modules attached to a base frame suitable for field mounting.

FIG. 24B illustrates a base frame for field mounting of photovoltaic meta-modules.

FIG. 25 illustrates photovoltaic meta-modules attached to a field-mounted base frame.

FIG. 26A illustrates a photovoltaic meta-module directly attached to retractable legs for field mounting.

FIG. 26B illustrates a photovoltaic meta-module field-mounted on directly attached legs.

FIG. 27 illustrates the joining of photovoltaic meta-modules to increase mechanical strength.

FIG. 28 illustrates the layout of electrical components of a photovoltaic meta-module.

FIG. 29A illustrates a pre-wired electrical assembly for interfacing a solar array having integrated DC-to-AC inversion to building electrical mains.

FIG. 29B illustrates a pre-wired electrical assembly for interfacing a solar array lacking integrated DC-to-AC inversion to building electrical mains.

FIG. 30 is a schematic of a pre-wired electrical assembly for interfacing a solar array to building electrical mains.

FIG. 31 illustrates a pre-wired electrical assembly for interfacing a solar array to building electrical mains.

FIG. 32 is a schematic of a pre-wired electrical assembly for interfacing a solar array to building electrical mains.

FIG. 33 illustrates a pre-wired electrical assembly for interfacing a solar array to building electrical mains.

FIG. 34 is a schematic of a pre-wired electrical assembly for interfacing a solar array to building electrical mains.

FIG. 35 illustrates a pre-wired electrical assembly for interfacing a solar array to building electrical mains.

FIG. 36 is a schematic of a pre-wired electrical assembly for interfacing a solar array to building electrical mains.

FIG. 37 illustrates a meta-module mounted on a small building.

### DETAILED DESCRIPTION

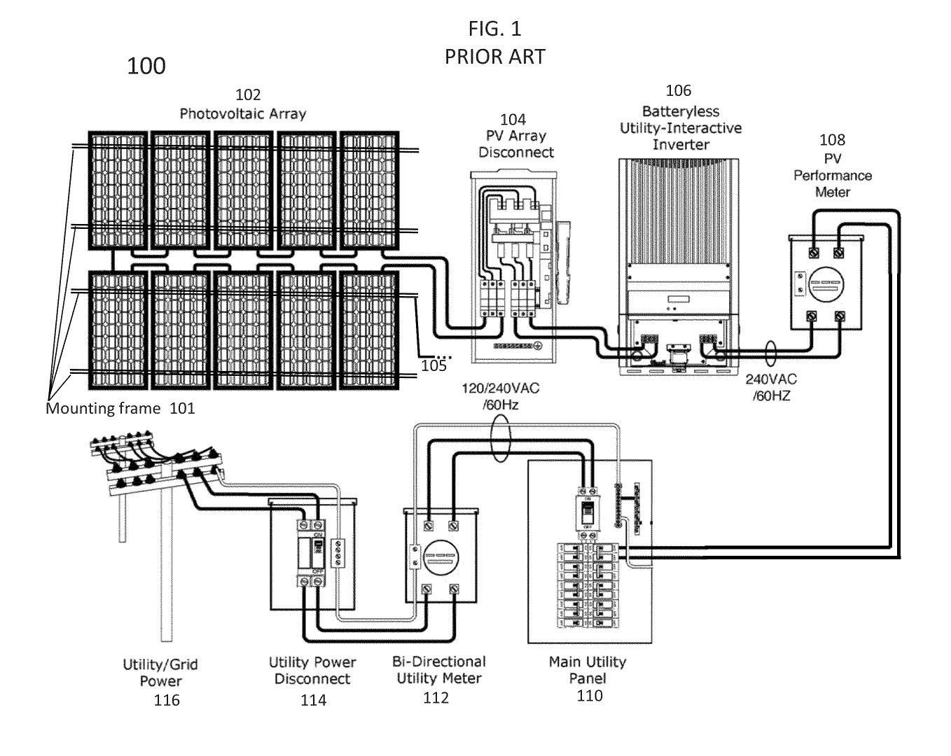

FIG. 1 depicts an illustrative system 100 according to the prior art for the generation of electricity by a residential-scale, grid-connected photovoltaic system. A photovoltaic array 102 is installed on a mounting frame 101, which is cut to length and installed via clips, bolts, and other hardware (not shown) by skilled laborers at the installation site on the rooftop or other location (e.g. ground mount pole or rack). The array 102 is assembled on the rooftop by laborers carrying individual solar panels to the rooftop (or other location) and affixing them to the mounting frame with clips, bolts, or other hardware (not show). Herein, a “solar panel” is a complete, environmentally protected unit capable of being manually carried to a rooftop by an average worker and consisting of pre-wired photovoltaic cells that generates DC power (or AC power, when the solar panel is fitted with a microinverter) when exposed to light. The individual solar panels are then interconnected at the installation site on the rooftop (or other location) by a skilled laborer or electrician. This wiring results in a reduced number (e.g. one per ten solar panels) of direct current (DC) connections to a PV-array disconnect box 104, typically located a distance from the solar panels 102 (e.g. on the side of the house). Additional on-site (e.g. on the rooftop or other location) wiring of the solar panels and frame is done (not shown) to develop a common equipment ground (105) which is then further wired (as indicated by ellipses) typically terminating at a grounding rod (not shown). The disconnect box 104 is connected to a utility-interactive inverter 106. The inverter 106 is connected (e.g. at single phase 240 VAC/60 Hz connection or other AC connection (e.g. 3-phase AC)) to a photovoltaic performance meter 108 (also known herein as a “solar meter”). In other installations (not shown), each solar panel in array 102 is individually connected to a microinverter and on site laborers wire microinverters together in a manner similar to the DC indicated above and are then wired to solar meter 108. The solar meter 108 is connected to a main utility box and breaker box 110. The main utility box and breaker box 110 for a household is typically located inside of home and requires custom electrical work inside the house for connection. The main utility box and breaker box 110 is typically already connected to a bi-directional utility meter 112, which may be connected to a utility power disconnect box 114, which is connected to a utility-operated power grid 116. The main utility box 110 is connected to various loads, not shown; the power required by loads connected to the main utility box 110 may be greater or less than the power supplied by the inverter 106. When the power required by loads connected to the main utility box 110 is greater than the power supplied by the inverter 106, the balance is drawn from the grid 116; when it is less, the excess is absorbed by the grid 116. The bi-directional utility meter 112 will record which way power is flowing—from the grid 116, or to the grid 116—in order that the owner of the system 100 may be credited or charged accordingly.

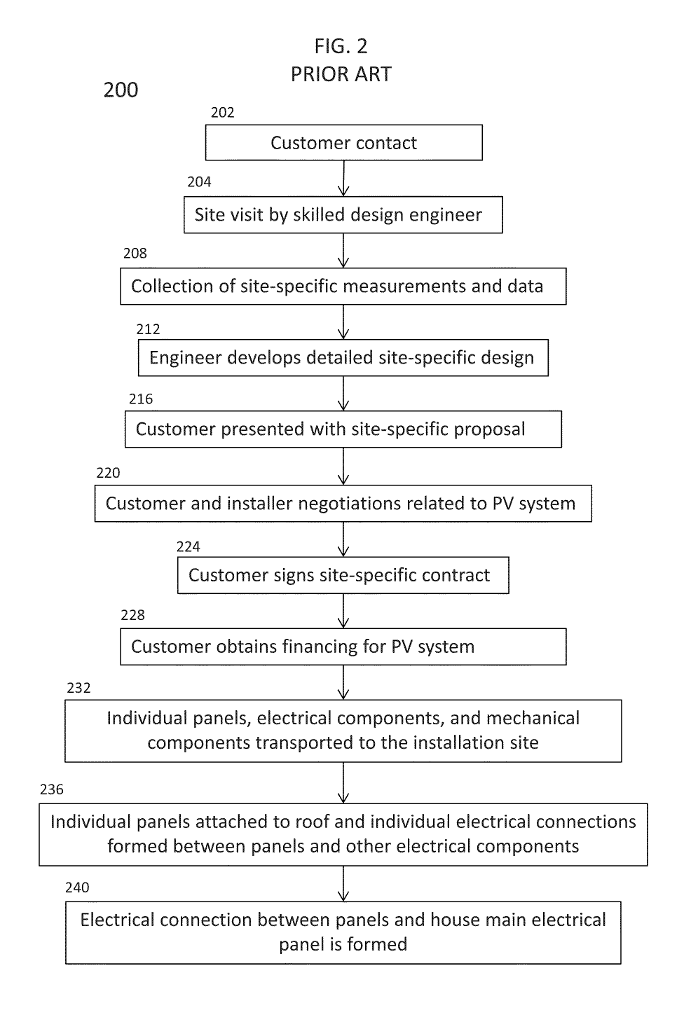

Referring to FIG. 2, there is shown a prior-art method 200 for a completed customer acquisition of a photovoltaic (PV) system for a residential installation. The process begins with a customer contact 202, e.g., customer inquiry or a company initiated marketing effort such as a sales call, a sales visit or a mailing. A frequent next step for a customer seriously considering a PV installation is a site visit 204 by a skilled design engineer. This visit will frequently include extensive measurements and data collection 208 of the proposed generation site as well as a recording of the site's solar generation potential using various tools such as a solar pathfinder. Based on site-specific details, the skilled design engineer will develop a detailed site-specific design 212 detailing the mechanical and electrical system configuration, including number and orientation of solar panels and the wiring layout. Next, the customer is typically presented with site-specific proposal 216 to build the site specific design for a site-specific cost. After review of the proposal, the potential customer may enter negotiations 220 with the PV system installer with regards to system details and/or cost. After any modifications to the proposal, a customer desiring to proceed will sign a site-specific contract 224. To pay for the PV system, the customer must often obtain financing 228 through an independent source such as a local bank providing a home equity loan. The installation of the PV system involves transport 232 of the individual solar panels, electrical components, and mechanical components to the installation site. For, e.g., a residential roof-top installation, these components are then hauled to the rooftop (usually by manual labor, up a ladder), where the solar panels are individually attached to the roof and the electrical connections between the panels and any other components, such as a micro-inverters if present, are formed 236. As the rooftop installation process involves mechanical and electrical aspects, the installation typically includes skilled electrical and mechanical technicians and/or electricians who must complete the tasks on site and usually on the roof. Once wired together, the electrical installation often includes feeding wiring through the house interior to make electrical contact with the house main utility box and breaker box 240. Additional wiring to power disconnects and solar meters may take place inside or outside of the house. In many typical prior art installations, the process of completing the end-to-end process 200, from sales initiation to completed system, can take six weeks or more.

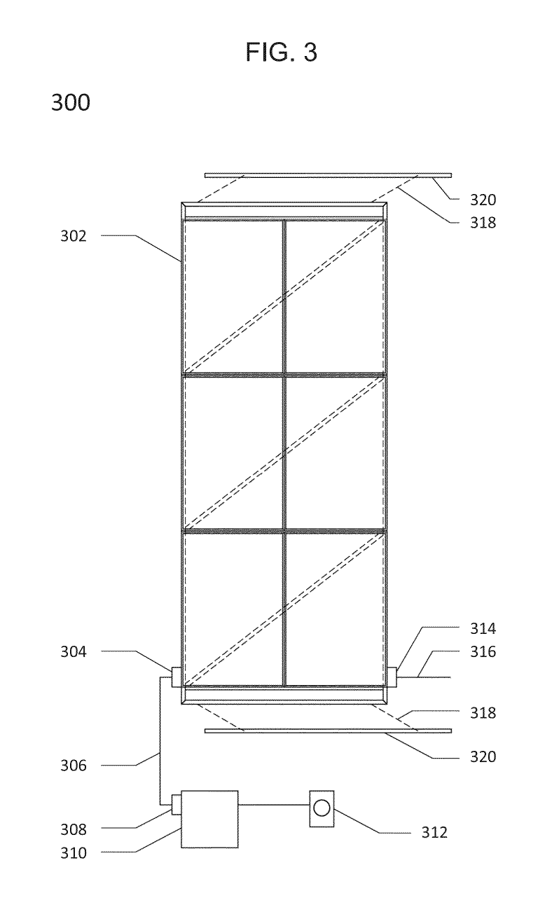

FIG. 3 schematically depicts the components of an illustrative installed system embodying the invention. In one embodiment, the illustrative solar meta-module 302 is transportable by truck (e.g., less than 8.5 ft wide), able to be lifted by a boom as a single pre-assembled piece, and comprises an array of solar panels of given number and size (e.g., six solar panels each 58″ by 78″ and each with 400 W nominal DC output power under full sun), a structural frame fitting the solar panel array, electrical components such as micro-inverters, and electrical wiring as needed to connect the solar panel array and other components. In one embodiment, the meta-module 302 is less than 8.5 feet wide to facilitate simpler transport by truck. In addition in one embodiment, the electrical wiring within the meta-module may terminate as illustrated in FIG. 3 at an electrical “Quick-connect” 304 attached to the meta-module frame. As used herein, a Quick-connect electrical connection is any electrical connection formable by hand, using simple tools or no tools, with connection taking place in a short period of time. In some embodiments the connection is made in a few seconds (e.g., no on-site removal of wire insulation, application of wire nuts, or other labor-intensive manipulations). In some embodiments, a Quick-connect connection will comprise a plug-and-jack combination.

In the embodiment illustrated, an electrical cable 306 with corresponding Quick-connect terminations connects the EZPV meta-module to a Quick-connect 308 attached to a pre-wired box 310 that contains all disconnects, fuses, and solar meter. In the illustrative embodiment shown, the connection from the pre-wired solar interconnection box 310 to the existing utility service meter 312 can be made without entering the house or other building. A second electrical Quick-connect 314 may be provided on the meta-module to enable linking multiple meta-modules together in the current or future installation using Quick-connect compatible wiring 316.

In the embodiment shown in FIG. 3 the solar meta-module frame is fastened by a suitable number of tethers or joiners 318 that connect easily to a mounting bar system 320. The mounting bar system 320 can be anchored to a roof or other portion of a building, or may be pole-mounted, or may be anchored to an extensive rack as for a utility-scale installation on dedicated acreage. In other embodiments (not shown) the meta-module frame can be additionally secured by the use of tethers that connect the frame with secure locations on other portions of the roof such as edges, corners or other suitable anchor points.

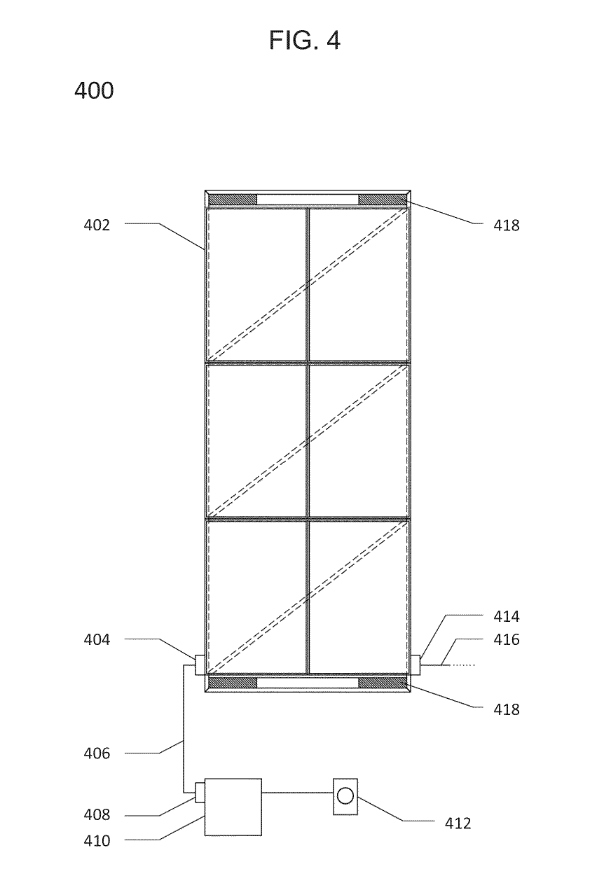

FIG. 4 schematically depicts the components of an illustrative installed system 400 embodying the invention. In one embodiment, the illustrative solar meta-module 402 is transportable by truck (e.g., less than 8.5 ft wide), able to be lifted by a boom as a single pre-assembled piece, and comprises an array of solar panels of variable size and number, a structural frame fitting the solar panel array, electrical components such as micro-inverters, and electrical wiring as needed to connect the array and components. In one embodiment the meta-module 402 is less than 8.5 feet wide to facilitate simpler transport by truck. In addition, the electrical wiring within the meta-module may terminate as illustrated in FIG. 4 at a standardized electrical connection 404, herein also termed a Quick-connect, that is attached to the meta-module frame. In the embodiment illustrated, an electrical cable 406 with corresponding Quick-connect terminations connects the meta-module 402 to a Quick-connect 408 attached to a pre-wired box 410 that contains all disconnects, fuses, and solar meter. A connection from the pre-wired box 410 to the existing utility service meter 413 can be made without entering the house or other building on which the system 400 is mounted. A second electrical Quick-connect 414 may be provided on the EZPV meta-module 402 to enable linking multiple meta-modules (not shown) together using Quick-connect compatible wiring 416.

In the embodiment shown in FIG. 4, the EZPV meta-module 402 is not physically anchored to the roof or other surface on which it is installed via attachments but held in place, even in the instance of high winds, by means of its weight which may include ballasts 418, which may be built into the frame. In various embodiments, the entire solar meta-module including ballasts 418 may be lifted as a single pre-assembled piece via boom truck or other lifting mechanism (e.g. telehandler, crane, forklift). In another embodiment, the solar meta-module may be lifted as a single pre-assembled piece and the ballast may be lifted separately and added by workers after mounting on the roof or other surface.

FIG. 5 depicts one method by which the solar meta-module 502 may be hoisted from a truck or other surface to the site of installation (e.g. rooftop, pole mount, rack) using a sling 504 attaching to points near the four corners of the frame of the meta-module 502. The sling 504 may be hoisted by a boom truck (not shown) or other lifting mechanism (e.g. telehandler, crane, forklift) equipped with a hook 506. The length of each cable or chain of the sling may be adjusted in order to lift the meta-module at approximately the same angle as the roof or other surface upon which it will be installed.

In the illustrative embodiment of FIG. 5 and various other embodiments of the invention, the EZPV meta-module is distinguished from the prior art in that its design (e.g., panel layout) and cost are not site-specific.

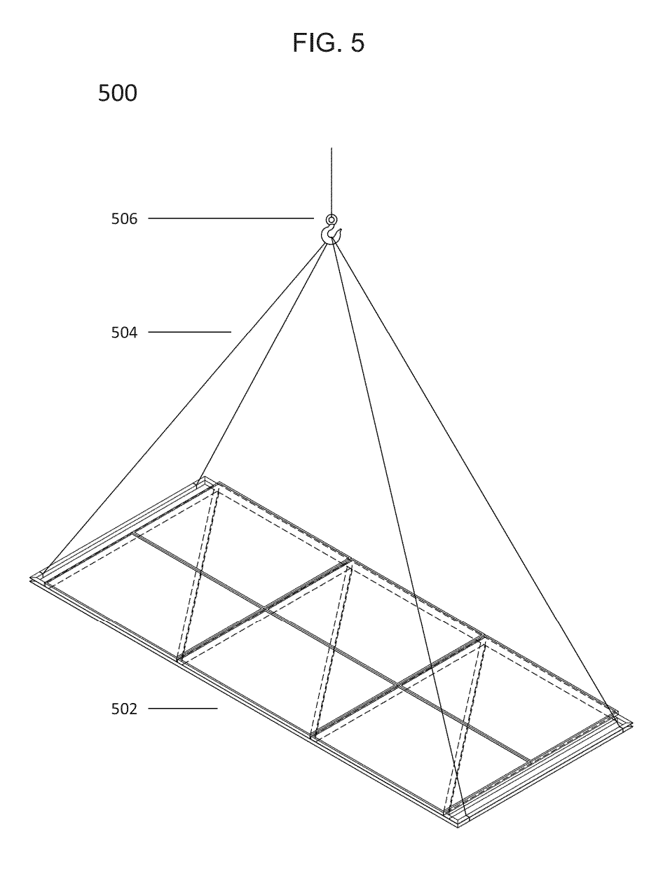

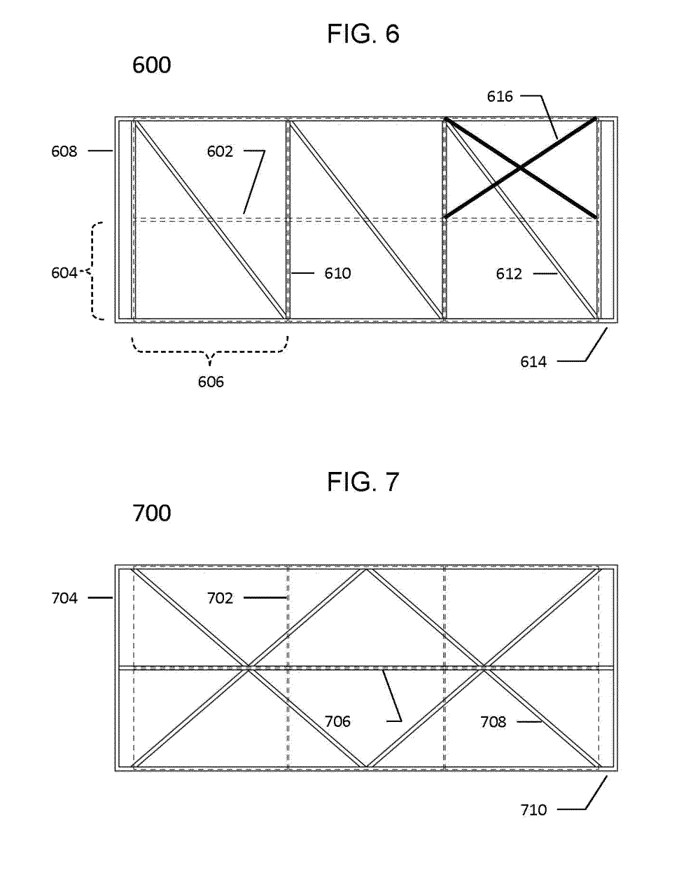

FIG. 6 depicts one embodiment of a solar meta-module with a pre-fabricated structural framing system 600 that supports an array of a given number and size (e.g., six solar panels each 58″ by 78″ and each with 400 W nominal DC output power under full sun) of solar panels, which are shown by rectangles of broken lines 602. The meta-module consists of at least two solar panels and typically four or more panels. The solar panels typically have standardized dimensions for width 604 (e.g. 12 to 58 inches) and length 606 (e.g. 24 to 78 inches) and are sufficiently small and lightweight (e.g. less than 75 pounds) that they can be manually carried by a worker to a rooftop. In the embodiment shown in FIG. 6, the structural system includes perimeter framing members 608, transverse framing members 610, and diagonal framing members 612, each of which has a profile (e.g., C-channel, I-beam) engineered to accommodate in-plane and out-of-plane loads and to facilitate pre-fabrication. The perimeter framing can extend beyond the solar panel array on one or more sides 614 to allow for mounting of electrical connectors and to provide points for hoisting the frame by sling or other method, and for anchoring the frame to its installation site. In one embodiment, the outer dimensions of the meta-module including framing system 600 are less than those needed to fit on a standard trailer truck (i.e., maximum width of 8 feet 6 inches, maximum height of 13 feet 6 inches minus bed height) for ease of transportation. In another embodiment, the framing system 600 is designed to undergo deflection less than a specified value (e.g. no more than 1″ deflection per 175″ of length) when lifted by a finite number of lifting points (e.g. 4 strap locations as indicated in FIG. 5). In particular, the frame may be designed such that when lifted from four strap locations on its periphery, the glass covering in any attached solar panels does not deflect more than a pre-specified value (e.g. no more than 1″ deflection per 175″ of length, no more than 1″ per 100″ of length).

In some embodiments, the meta-module may contain an interrupted (i.e., not fully occupied) array of PV panels; that is to say, within the array pattern of the framing system layout, one or more PV panels may be omitted to leave an opening 616 (e.g., as indicated by the ‘X’) or openings if necessary in order to accommodate existing or planned obstacles (e.g. chimneys, stacks, vents, dormers, mechanical units and other rooftop equipment, projections, or access points), over or around which the framing system could span. In this way, the structural system is versatile and may provide advantages to reduce roof penetrations and installation time.

FIG. 7 depicts another embodiment of a solar meta-module with a pre-fabricated structural framing system 700 that supports an array of a given size and number of solar panels, which are shown by rectangles of broken lines 702. In the embodiment shown in FIG. 7, the structural system includes perimeter framing members 704, one or more longitudinal interior framing members 706, and diagonal framing members 708, each of which has a profile engineered to accommodate in-plane and out-of-plane loads and to facilitate pre-fabrication. The perimeter framing can extend beyond the solar panel array on one or more sides 710 to allow for mounting of electrical connectors and to provide points for hoisting the frame by sling or other method, and for anchoring the frame to its installation site.

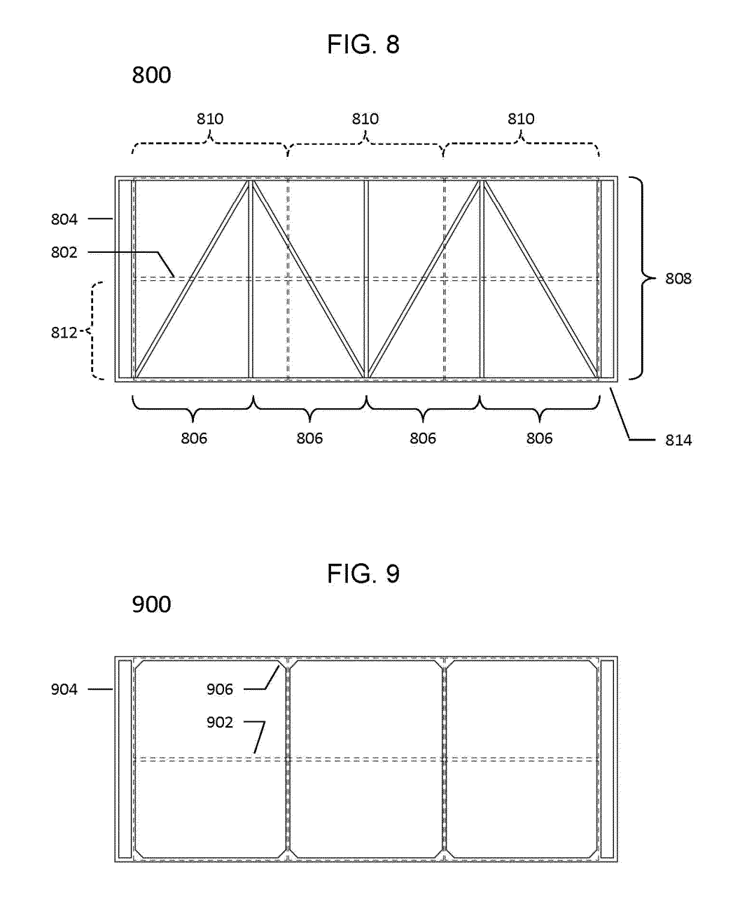

FIG. 8 depicts another embodiment of a solar meta-module with a pre-fabricated structural framing system 800 that supports an array of a given size and number of solar panels, which are shown by rectangles of broken lines 802. In the embodiment shown in FIG. 8, the structural system includes perimeter framing members 804 and additional interior framing members, both transverse and diagonal, as shown by continuous lines. In the embodiment shown in FIG. 8, the framing system is configured in repeated structural bays of longitudinal dimensions 806 and transverse dimensions 808, which may or may not equal, or be integral multiples of, the corresponding solar panel longitudinal dimensions 810 and transverse dimensions 812, in order to enable structural efficiency and ease of connections within the meta-module. The perimeter framing can extend beyond the repeated structural bays on one or more sides 814 to allow for mounting of electrical connectors and to provide points for hoisting the frame by sling or other method, and for anchoring the frame to its installation site.

FIG. 9 depicts another embodiment of a solar meta-module with a pre-fabricated structural framing system 900 that supports an array of a given size and number of solar panels, which are shown by rectangles of broken lines 902. In the embodiment shown in FIG. 9, the structural system includes framing members 904 that are engineered to accommodate in-plane and out-of-plane loads, and that are joined by rigid moment connections 906, which may be fabricated by welding, by using gusset plates, or by other means.

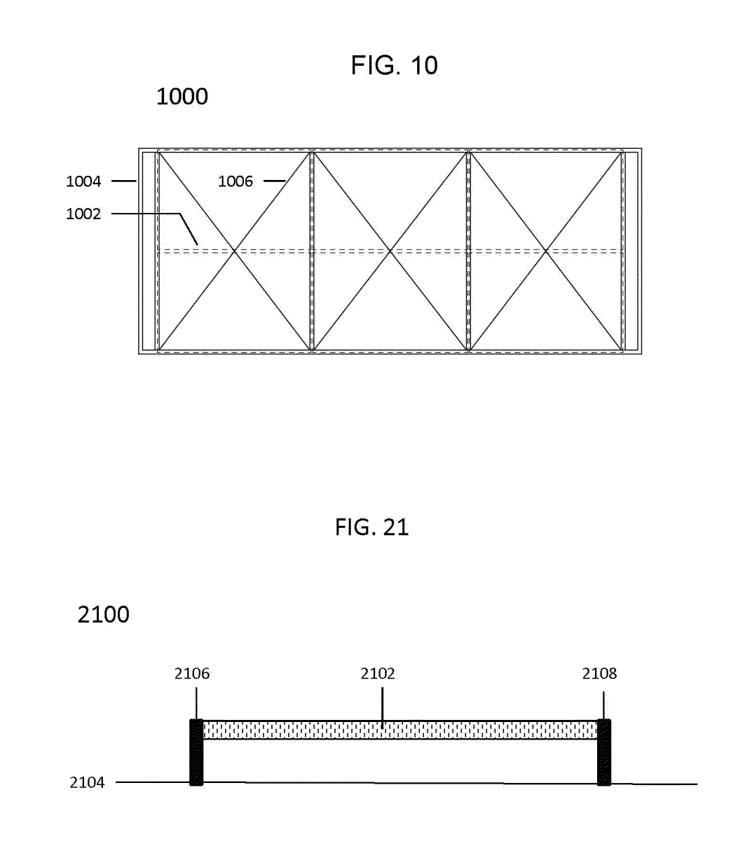

FIG. 10 depicts another embodiment of a solar meta-module with a pre-fabricated structural framing system 1000 that supports an array of a given size and number of solar panels, which are shown by rectangles of broken lines 1002. In the embodiment shown in FIG. 10, the structural system includes rigid framing members 1004 and tensile cross-bracing 1006, such as metal cables, as needed to resist lateral loads.

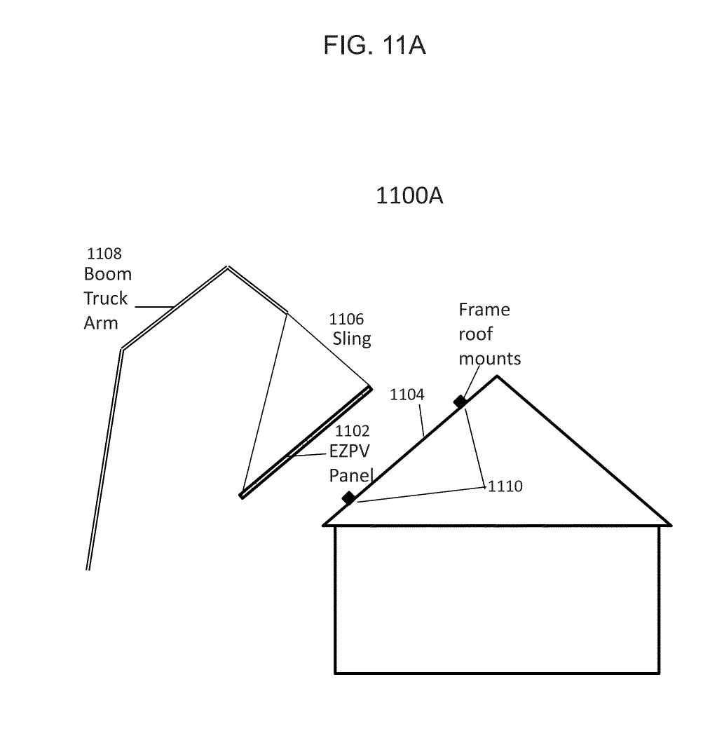

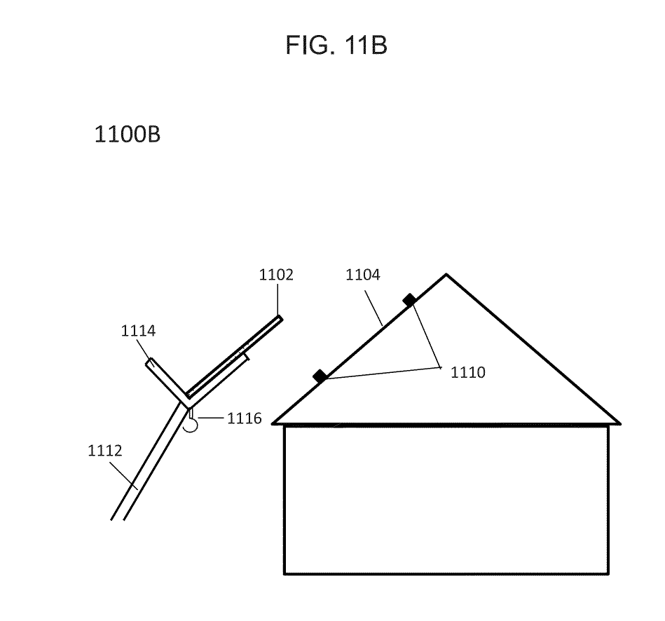

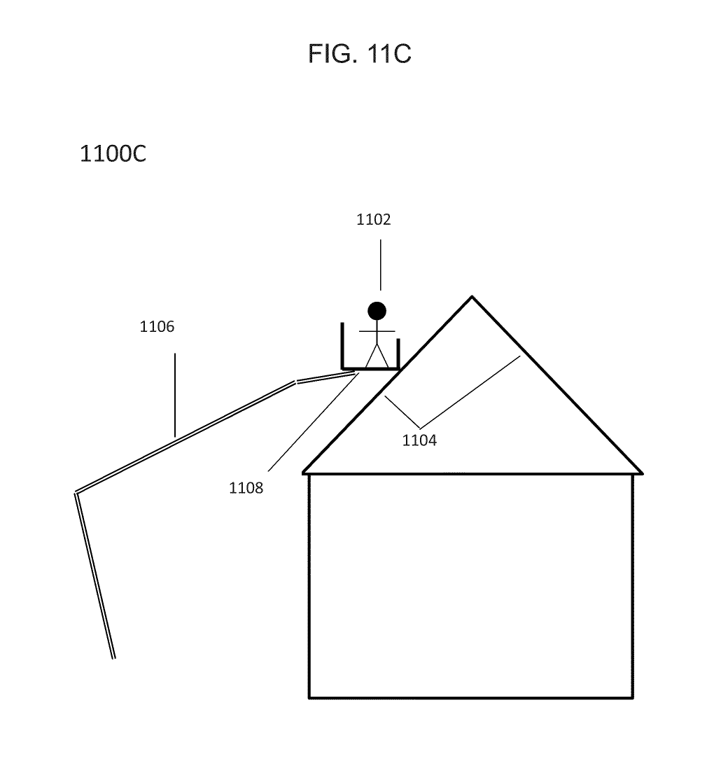

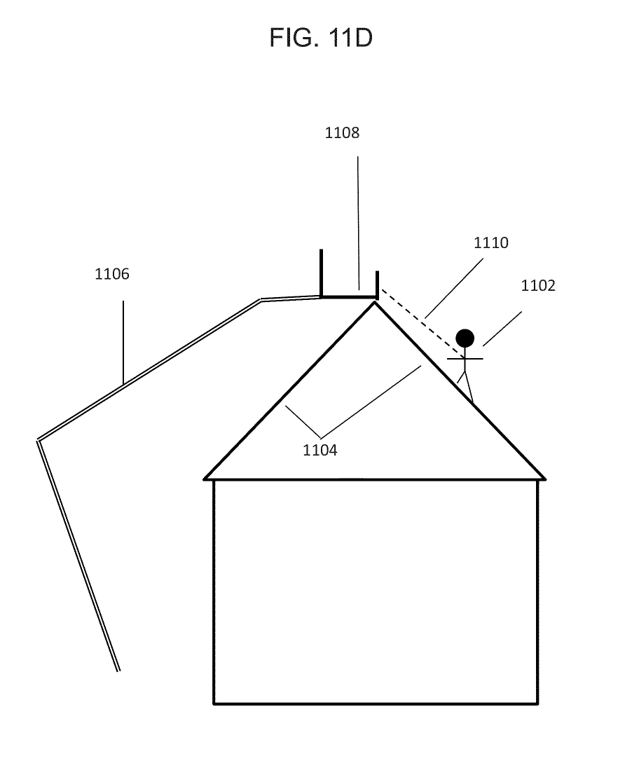

FIG. 11A depicts an illustrative method 1100 according to the invention for the delivery and attachment of an illustrative planar photovoltaic meta-module (also herein termed an “EZPV meta-module”) 1102 to the planar roof 1104 of an illustrative structure (here depicted in cross-section). In FIG. 11A, the roof 1104 is depicted as angled, but in various embodiments the roof 1104 may be in any position, including horizontal, that allows sunlight to shine upon the meta-module 1102. The meta-module 1102 may be hoisted by a sling 1106 similar to that depicted in FIG. 5, said sling 1106 hoisted by suitable crane or other device 1108 (e.g., a boom truck arm). In the illustrative method 1100 depicted in FIG. 11, the sling 1106 is adjusted so that the meta-module 1102 is suspended at an angle approximately equal to the angle of the roof 1104. Frame roof mounts 1110 are pre-attached to the roof 1104, and when the meta-module 1102 is lowered approximately into contact with the roof mounts 1110, the meta-module 1102 is attached to the roof mounts by workers (not depicted) or automatic connection (e.g. spring-loaded clips). Approximately matching the hang angle of the hoisted meta-module 1102 and the roof 1104 enables faster, simpler attachment to the roof mounts 1110. As depicted in FIG. 11A, the meta-module 1102 is mounted parallel to the roof 1104, but in various embodiments the frame roof mounts 1110 may be sized and positioned in such a manner that the meta-module 1102 is not, when mounted, parallel to the roof 1104: in some of these embodiments, the hang angle of the hoisted meta-module 1102 may be adjusted to correspond to the angle of final installation, rather than the angle of the roof 1104.

FIG. 11B depicts an illustrative method 1100B according to the invention for delivery and attachment of an illustrative EZPV meta-module 1102 to a planar roof 1104 of an illustrative structure (here depicted in cross-section). In FIG. 11B, the roof 1104 is depicted as angled, but in various embodiments the roof 1104 may in any position, including horizontal, that allows sunlight to shine upon the EZPV meta-module 1102. The EZPV meta-module is lifted to the roof using a telehandler 1112 (or other mechanized lifting mechanism) with fork attachment 1114. Alternatively, meta-module may be slung below the telehandler through the use of a lifting hook (1116). In the illustrative method 1100B, the fork lift 1114 is raised at an angle approximately equal to the angle of the roof 1104. Frame roof mounts 1110 are pre-attached to the roof 1104 and when EZPV meta-module 1102 is raised approximately into contact with the mounts 1110, the EZPV meta-module 1102 is attached to the roof mounts 1110 by workers or automatic connection (e.g. spring-loaded clips) and the fork lift 1114 is retracted. Approximately matching the angle of the raised EZPV meta-module 1102 and the roof 1104 enables faster, simpler attachment to the roof mounts 1110. As depicted in FIG. 11B, the EZPV meta-module 1102 is mounted parallel to the roof 1104, but in various embodiments the frame roof mounts 1110 may be sized and positioned in such a manner that the EZPV meta-module 1102 is not, when mounted, parallel to the roof 1104: in some of these embodiments, the angle of the lifted EZPV meta-module 1102 may be adjusted to correspond to the angle of final installation, rather than the angle of the roof 1104.

FIG. 11C depicts aspects of an illustrative method 1100C according to the invention for enabling access by a human worker 1102 for attachment of an EZPV meta-module (e.g., meta-module 1102 of FIG. 11B; not shown in FIG. 11C) to the roof 1104 of an illustrative structure. The worker 1102 is lifted to the roof 1104 by a device 1106 (e.g., boom truck as depicted in FIG. 11C, telehandler, scissor lift, or other personal lifting device) on a work platform 1108. The worker 1102 may do all installation work from work platform 1108, or may work on a scaffolding proximate to the roof 1104, or may stand upon the roof 1104 itself if the slope of the roof 1104 is sufficiently slight and/or the worker 1102 is secured to the roof 1104 or platform 1108 by a safety harness. The worker 1102 may be secured to both the platform 1108 and/or to the roof 1104 for additional safety. The method 1100C may be extended to the movement of more than one worker either simultaneously or sequentially.

FIG. 11D depicts further aspects of the illustrative method 1100C of FIG. 11C. The worker 1102 is standing on the roof 1104 (e.g., in order to attach anchoring hardware, not shown, or guide and attach meta-module, not shown, during installation) and is attached by a tether 1110 (e.g., adjustable-length and/or shock-absorbing type) to the platform 1108 of a boom truck, telehandler, or other lifting device 1106. In the method 1100C, the worker 1102, wearing a body harness (not shown), is connected by the tether 1110 solely to the platform 1108, but in various embodiments the worker 1102 may be attached simultaneously or separately to the lifting device 1106 or to another point of attachment not depicted (e.g., scaffolding, another permanent structure).

In the illustrative method 1100C, aspects of which are depicted in FIG. 11C and FIG. 11D, and various other embodiments, all lifting devices, tethering and harnessing arrangements, and arrangements for the clothing and equipping of the worker 1102 would conform to applicable manufacturer specifications and safety regulations (e.g., in the USA, regulations of the Occupational Safety and Health Administration). The methods for mechanically lifting workers to the roof and tethering to elevated work platforms shown in FIGS. 11C and 11D may increase worker safety (e.g., by avoiding ladders, reducing times when workers are not tethered such as when installing safety anchors and avoiding site installed anchors that are potentially prone to improper installation) and productivity (e.g., by speeding rooftop access and enabling greater mobility and safety for workers). Multiple lifting devices may be used simultaneously to further speed installation and improve worker safety. For example, one lifting device may be used by a rooftop worker for a work platform or safety tether, and at the same time a second lifting device may be used to lift a meta-module to the rooftop for final guidance and attachment by the rooftop worker.

The illustrative structures of FIGS. 11A-11D are depicted as having symmetrical pitched roofs, but structures having level and/or asymmetrically pitched roofs, as well as structures whose rooflines mingle level, pitched, and/or non-planar portions, are also contemplated and within the scope of the method 1100C and other embodiments.

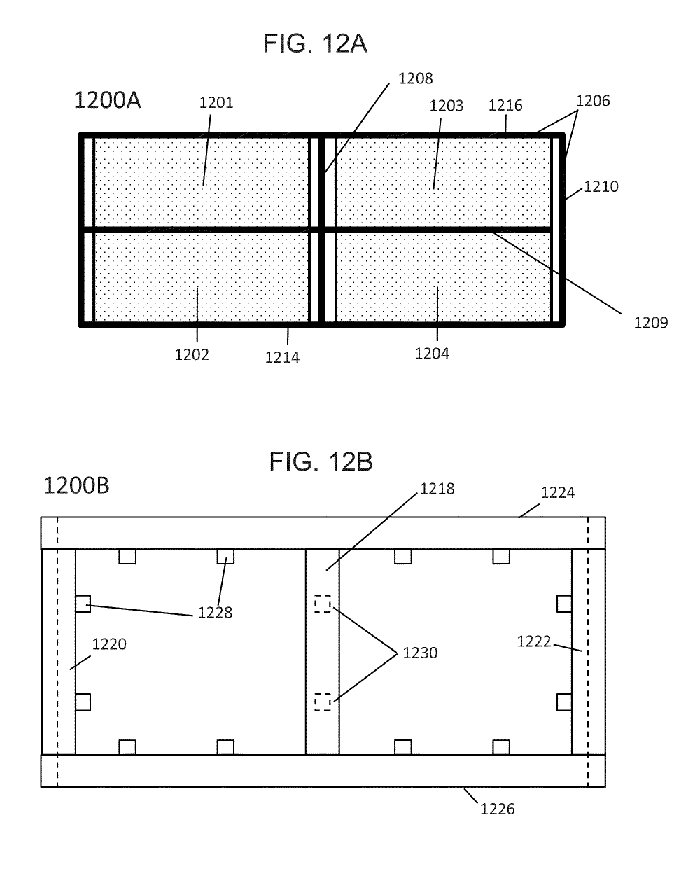

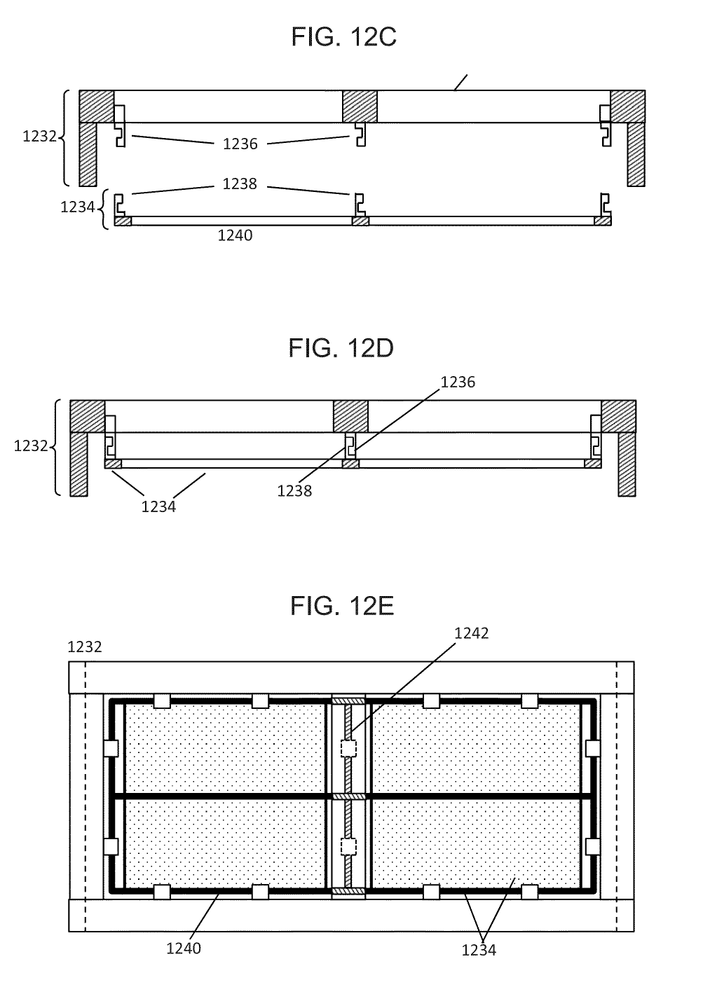

In FIG. 12A through FIG. 12D there is shown a system according to the invention for the assembly of a PV system for rapid and low-cost installation on commercial and residential roof tops and for large and small field installations. According to one embodiment, a relatively strong, rigid lift frame is developed that is capable of supporting an EZPV meta-module. FIG. 12A is a schematic top-down view of an illustrative EZPV meta-module 1200A. The meta-module 1200A comprises multiple solar panels 1201, 1202, 1203, 1204 (represented in FIG. 12A by stippled rectangles), a supportive framework 1206, electrical hardware (not shown), and hardware (not shown) for connecting the framework 1206 to both a lift frame (e.g., frame 1200B in FIG. 12B) and also to mounting hardware (e.g., on a rooftop: not shown). The module 1200A comprises four solar panels 1201, 1202, 1203, 1204 but in various other embodiments may comprise any number of solar panels equal to or greater than one. The illustrative framework 1206 comprises two mid-members 1208, 1209, two end members 1210, 1212, and two side members 1214, 1216. The framework 1206 is of sufficient strength to secure the solar panels 1201, 1202, 1203, 1204 against wind, gravity, and other forces when the framework 1206 is attached to mounting surface (e.g. rooftop) and hardware (e.g., clips, bars, ballast), but may not be of sufficient strength to prevent unacceptable sagging and bowing of the module 1200 if lifted directly (e.g., by the corners). The illustrative framework 1206 may be less expensive than a structural frame capable of being lifted directly and may consist of lower cost materials and fabrication methods (e.g. an extruded or molded plastic frame).

FIG. 12B is a schematic top-down view of a lift frame 1200B (or exoskeleton) that functions in conjunction with the meta-module 1200A in FIG. 12A. Lift frame 1200B comprises a mid-member 1218, two end members 1220, 1222, and side members 1224, 1226, and lift connectors (e.g., lift connectors 1228). Two lift connectors 1230 (indicated by dashed rectangles) are mounted on the underside of the mid-member 1218. The use of the lift connectors is illustrative, where any number of lift connectors more than one is contemplated and where other mechanisms for securing the meta-module are contemplated.

FIG. 12C is a schematic cross-sectional side view of a lift frame 1232 and a meta-module 1234. Lift frame 1232 is positioned above the meta-module 1234; the lift connectors (e.g., connectors 1236) of the lift frame 1232 are positioned above correspondingly placed lift connectors (e.g., 1238) on the module supportive framework 1240.

FIG. 12D is a schematic cross-sectional side view of the lift frame 1232 and a meta-module 1234 of FIG. 12C. Lift frame 1232 is attached to the meta-module 1234; the lift connectors (e.g., connector 1236) of the lift frame 1232 are connected to the correspondingly placed lift connectors (e.g., 1238) on the meta-module 1234. In this configuration, the joined lift frame 1232 and meta-module 1234 may be lifted by an appropriate device (e.g., forklift, crane, boom) for loading and unloading and for placement at an installation site (e.g., rooftop).

FIG. 12E is a schematic top-down view of the joined lift frame 1232 and EZPV meta-module 1234 of FIG. 12D. Portions 1242 of the module supportive framework 1240 that are obscured by the mid-member 1218 of the lift frame 1232 are represented by cross-hatched bars. The dimensions, number, type, and layout of panels, framework and lift-frame members, and lift connectors may all differ, in various embodiments, from those shown in FIG. 12A through FIG. 12E, which are schematic and illustrative only. Hardware not depicted in FIG. 12A through FIG. 12E (e.g., eyelets for the attachment of lifting hooks, electrical wiring, electrical connectors, devices for control and/or monitoring) may be comprised by the lifting frame and/or the EZPV meta-module in various embodiments.

In various embodiments, the system depicted in FIG. 12A through FIG. 12E may be employed as follows: a EZPV meta-module is attached to a lifting frame as depicted in FIG. 12D, either before transport to the installation site or at the installation site. The lift frame is then moved into a position (e.g., by the method of FIG. 11A or FIG. 11B) such that the EZPV meta-module may be attached readily to pre-installed mounting hardware. The EZPV meta-module is then detached from the lift frame, which may be re-used, either at the same worksite or at other worksites. An advantage realized by this system is that the supportive framework of the EZPV meta-module need not be strong enough to resist unacceptable distortion while being lifted into position. The EZPV meta-module may therefore be lighter and less costly. Costly materials needed to provide a sufficiently rigid frame may be restricted to the lift frame and shared over many (e.g., hundreds) of installation procedures. In distinction from the prior art, the solar panels of the EZPV are not attached directly to the mounting surface (e.g., roof); rather, the supportive framework of the EZPV meta-module may be attached directly to, or anchored frictionally upon, the mounting surface.

In another embodiment, the lifting frame (e.g. 1200B) is designed to undergo deflection less than a specified value (e.g. no more than 1″ deflection per 175″ of length) when lifted by a finite number of lifting points (e.g. 4 strap locations as indicated in FIG. 5). In particular, the frame may be designed such that when lifted from a finite number of lifting locations (e.g. 4), the glass covering in any attached solar panels does not deflect more than a pre-specified value (e.g. no more than 1″ deflection per 175″ of length, no more than 1″ per 100″ of length).

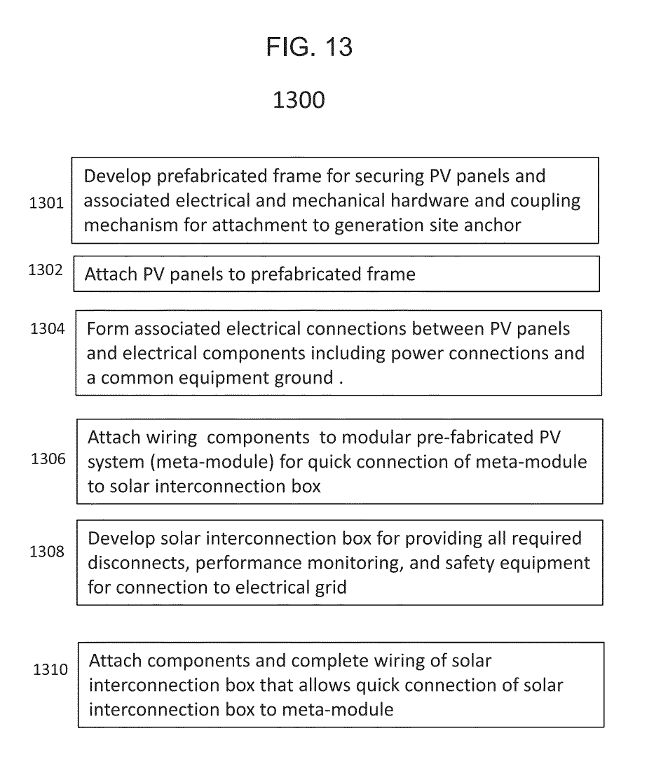

Referring to FIG. 13, there is shown a method 1300 according to aspects of the invention for the assembly of a modular prefabricated photovoltaic system for rapid and low cost installation on commercial and residential roof tops and for large and small field installations. According to one embodiment, a frame is developed that is capable of supporting the solar panels and associated mechanical and electrical hardware 1301. In one embodiment, the design of the frame is assembled in a pre-fabricated fashion to facilitate the integration of the panels and electrical and mechanical connections in an efficient manner in a factory type environment. This pre-fabrication can include holes and attachment structures used to attach the solar panels to the frame and to secure wiring and other electrical and mechanical components in robust and easy manner. Another component of the frame design includes structures to allow the relatively simple and quick attachment of the frame and its associated components to the generation site via site anchors. These anchor attachment structures can include bolts, compression fittings, carabiners, quick release mechanisms, and any other mechanical connections designed to provide secure and relatively rapid attachments. The frame can be made from metal such as aluminum or steel or from a plastic or composite material. In one embodiment the frame material selection includes consideration of the ease and cost of manufacture as well as the environmental durability. In various embodiments, there can be a variety of frames designed for different panels or installation configurations.

The method 1300 includes attaching to the prefabricated frame the solar panels 1302. The attachment points for the panels can include commercially available hardware as well as engineered fittings. The method 1300 also includes forming the electrical connections 1304 between the panels and any associated electrical components. Electrical wiring may include wiring of power connections (e.g. DC positive and neutral wires, AC 240 V wiring, AC three-phase wiring) and grounding connections (e.g. equipment grounding of solar panel frames, metallic meta-module frame, microinverter metallic cases). In various embodiments these electrical components include micro-inverters, intelligent optimizers, sensors, and other devices. The inverters are used to convert the direct current voltage produced by the solar panels to the alternating current voltage required by the electrical service and may be part of the meta-module (e.g. microinverters) or may be part of the solar interconnection box (e.g. string inverter). The method 1300 further comprises connecting an electrical apparatus 1306 that will be used to form the electrical connection with the electrical wiring at the generation site. In one embodiment, the electrical connection is an easily formed electrical connection such as electrical socket or plug. For an embodiment with a socket, an electrical cable (e.g. multiple conductors insulated from one another and routed as a unit, potentially within a common conduit) with a plug can be readily attached with the other end of the cable to a solar interconnection box (e.g. comprising items such as disconnects, solar meter, data monitoring and reporting hardware and software, breakers). The solar interconnection box can also have a plug and socket connection for the cable coming from the EZPV meta-module panel assembly. In some embodiments the inverter for the modular prefabricated EZPV meta-module system can be separate from the solar panels and frame meta-module assembly and can be located with the installation location solar interconnection box or electrical service box. In one embodiment, additionally, a solar interconnection box is fabricated 1308 which comprises components for electrical safety (e.g. breakers, fuses, disconnects) and solar performance monitoring (e.g., solar meter, data monitoring and reporting hardware and software). Components for the solar interconnection box may be attached 1310 to a common frame for mounting and wired together in a factory setting including the attachment and wiring of a socket (or other quick-connection device) for connections to cable coming from EZPV meta-module. In certain embodiment, the solar interconnection box may be a separate component which is installed separate from the meta-module (e.g. on the side of the house or building, on a pole near the grid interconnection point) or may be part of the meta-module. The order of operation of the steps 1301, 1302, 1304, 1306, 1308, 1310 in method 1300 is varied according to different embodiments of the invention. For example, in some embodiments, wiring and mechanical connections 1304 are formed prior to the addition of the panels 1302 and in other embodiments, the panels are attached to the frame first. Some steps may be omitted in certain embodiments, such as steps 1308 and 1310, and completed in another manner (e.g. onsite development and wiring of solar interconnection box).

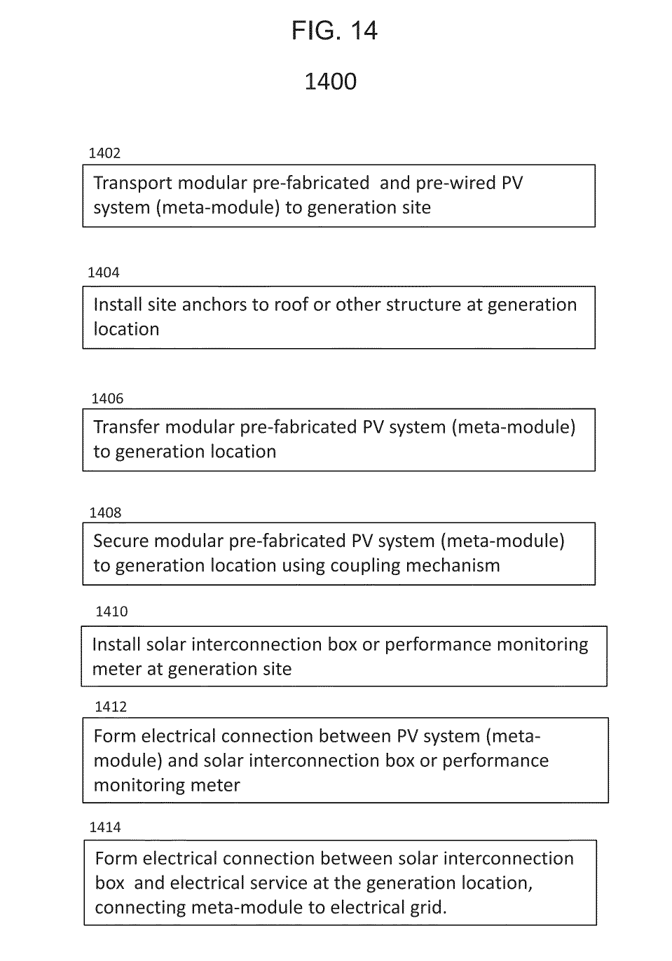

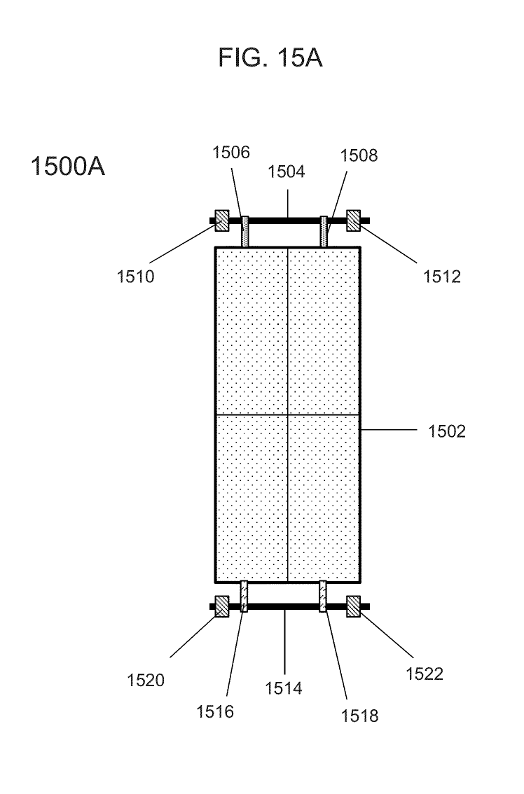

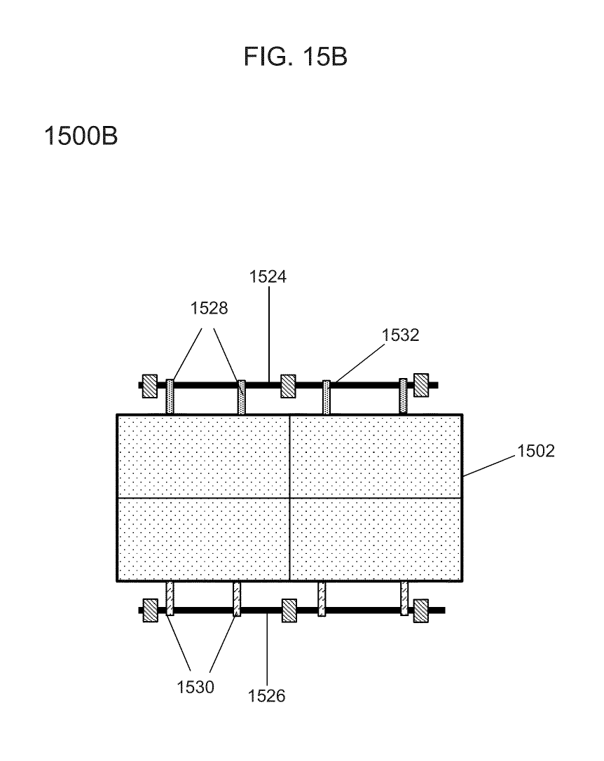

Referring to FIG. 14, there is shown a method 1400 for installing a modular pre-fabricated EZPV meta-module system at a generation site. The method 1400 includes transporting to the installation site the modular pre-fabricated EZPV meta-module system 1402. In various embodiments this transportation can occur via a truck or similar vehicle designed or outfitted to carry the modular pre-fabricated EZPV meta-module system. The method 1400 includes securing mounting anchor system 1404 at the generation location. As used herein, installation site refers generally to where the solar installation is to occur, such as at a particular residential or commercial address, and generation location refers to the final specific physical spot where the EZPV system will be placed, such as a particular spot on a roof for a residential or commercial rooftop installation. One can also refer to either the installation site and/or the generation location as the installation location, and the usage will make clear which of the installation site and/or the generation location is intended. In one embodiment for residential roof tops, the mounting anchors includes components for establishing a secure connection with the roof, such as clamps for standing seam roofs such as those sold by S-5! Inc. having a principal place of business at 8655 Table Butte Road, Colorado Springs, Colo. 80908, and sealed rafter bolts for shingle roofs such as those sold by PV Quick Mount having a principal place of business at 2700 Mitchell Dr., Bldg. 2 Walnut Creek, Calif. 94598. The mounting anchors also include elements for establishing secure and rapid mechanical connections with the modular pre-fabricated EZPV meta-module system and are discussed with respect to FIGS. 15-21. In other embodiments, the mounting anchor system can be integrated with a support structure deployed for the modular pre-fabricated EZPV meta-module system. In one embodiment for ground mount systems, the mounting anchor system is attached to the ground mount support frame. In one embodiment for flat commercial roof top installations, the mounting anchor system is attached to the rooftop support frame. These embodiments are discussed with respect to FIGS. 15-27. The method 1400 includes transferring the modular pre-fabricated PV system to the generation site at the installation location 1406 via a lifting mechanism. In one embodiment, the modular pre-fabricated EZPV meta-module system is transferred to the generation site via a lifting mechanism that comprises a boom hydraulic lift that includes an extendable boom and a retractable cable. In another embodiment, the modular pre-fabricated EZPV meta-module system is transferred to the generation site via a fork lift or hydraulic lift, such as a GENIE lift. In some embodiments, a crane is used to transfer one or more modular pre-fabricated EZPV meta-module systems. In additional embodiments, a combination of different transfer mechanisms is used. In one such embodiment for commercial rooftop installations, a crane or a lift is used to transfer the modular pre-fabricated PV systems to the roof top and fork lifts or other smaller mobile transport systems are used to distribute the modular pre-fabricated EZPV meta-module systems to the individual generation sites on the roof top. The method 1400 also includes attaching the modular pre-fabricated EZPV meta-module system to the mounting anchor system 1408. The method 1400 also includes forming an electrical connection between the modular pre-fabricated EZPV meta-module system and the electrical service at the installation location. The electrical connection may comprise the installation of a solar interconnection box which comprises components for electrical safety (e.g., breakers, fuses, disconnects) and solar performance monitoring (e.g., solar meter, data monitoring and reporting hardware and software) at the generation site 1410. The solar interconnection box may be pre-fabricated and attached to a common frame for mounting and wired together in a factory setting including the attachment and wiring of a socket (or other quick-connection device) for connections to cable coming from EZPV meta-module. In certain embodiment, the solar interconnection box may be a separate component which is installed separate from the meta-module (e.g. on the side of the house or building, on a pole near the grid interconnection point) or may be part of the meta-module. The method 1400 may include the formation of an electrical connection between the EZPV meta-module and the solar interconnection box 1412. The interconnection 1412 may be completed using an easily formed electrical connection such as electrical socket or plug. For an embodiment with a socket, an electrical cable (e.g. multiple conductors insulated from one another and routed as a unit, potentially within a common conduit) with a plug can be readily attached to the meta-module socket with the other end of the cable to a solar interconnection box socket. The method 1400 connection to the electrical grid may be completed by connection of the solar interconnection box to the electrical grid 1414. In one embodiment for residential rooftop solar, this electrical connection includes attaching an electrical cable from the modular pre-fabricated PV system to a solar meter attached to the residential electrical service. In one such embodiment, the electrical cable is fitted with a plug for rapid and easy connection to a socket on the solar meter. In another such embodiment, the electrical connection from the modular pre-fabricated PV system is made directly to the residential electrical service without some or all of steps 1410 and 1412. In various embodiments this connection is be made via a plug and socket connection and can include an integrated solar meter. In some embodiments the electrical connection to the utility service is completed without the wiring associated with the modular prefabricated PV system being connected to the electrical wiring internal to the installation location. In some embodiments, the inverter for the modular prefabricated PV system is separate from the prefabricated frame assembly and can be located with the solar meter and the wiring connections made to the installation location service. The form of the electrical connections are also discussed with respect to FIGS. 28-37. In various embodiments, the installation steps included in method 1400 are completed in less than hour. In other embodiments in which the installation is more complicated, the steps in method 1400 are completed in less than two hours, less than four hours, and less than eight hours. In various embodiments, sale and installation of an EZPV meta-module system may occur in a period of less than 24 hours. In some embodiments, the financing for the EZPV meta-module is provided by or through the entity, such as the power utility, that provides the grid connection. In one such embodiment, payments for the loan or lease associated with the EZPV meta-module are contained within a utility bill already received by a customer. One such embodiment is known in the art as “in-billing.”

The order of operation of the steps 1402, 1404, 1406, 1408, 1410, 1412, and 1414 in method 1400 is varied according to different embodiments of the invention. For example, in some embodiments, the solar interconnection box may be installed 1410 prior to installing the site anchors 1404. Some steps may be omitted in certain embodiments, such as steps 1410 and 1412, or completed in another manner (e.g. onsite development and wiring of solar interconnection box).

FIG. 15A depicts an embodiment of an illustrative planar, rectangular EZPV meta-module installation (i.e., EZPV meta-module) 1500A mounted in a portrait orientation, i.e., with a shorter edge of the EZPV meta-module 1502 more elevated than any other part thereof. The long axis of the meta-module 1502 is tilted at some angle to the horizontal; the short axis of the panel 1502 is horizontal. The view of FIG. 15A is at right angles to the panel 1502. The panel 1502 is attached to a first load bar 1504 by mechanical connectors 1506 and 1508 capable of bearing a tensile load. The connectors 1506 and 1508 may be carabiners, cable loops, spring-loaded clamps or other devices that allow connection between EZPV meta-module 1502 and the load bar 1504. A carabiner 1506, 1508 may attach to the supportive framework of the EZPV meta-module 1502 by an eyelet on the frame. A carabiner 1506, 1508 may pass over or through a hole in the load bar 1504. Load bar 1504 is strong enough to withstand forces acting on the EZPV meta-module 1502 (e.g., gravity, wind loading, snow) and communicated to the load bar 1504 through the connectors 1506, 1508. In various embodiments, the cross-sectional form of load bar 1504 may depend upon the method of connection of the load bar 1504 to the panel 1502 and to the roof or other mounting surface (not depicted), and/or upon roof conditions (slope of roof may affect how strong a load bar needs to be). The first load bar 1504 is connected to the mounting surface by connectors 1510 and 1512. The type of connector 1510 and 1512 employed depends upon the nature of the mounting surface. For example, for a standing-seam roof, the connectors 1510, 1512 may be S-5! metal clamps that attach to roof panel seams and do not penetrate the roof; or, for a composition/asphalt shingle roof, Quick Mount PV Classic Comp connectors may be used; or, for a tile roof, Quick Hook USA connectors may be used. The EZPV meta-module 1502 is connected at its lower edge to a second load bar 1514 by lower connectors 1516 and 1518. The second load bar 1514 is attached to the mounting surface by anchoring devices 1520, 1522 that are similar to anchors 1510, 1512. Connectors 1516 and 1518 may be tightenable and lockable in order that a permanent tensile force may be exerted on the upper connectors 1506, 1508 in addition to the force exerted by the weight of the EZPV meta-module 1502. For example, turnbuckles with locking nuts may be used for the lower connectors 1516, 1518. Angling of the turnbuckle toward the plane of the mounting surface (e.g., in FIG. 15A, into the plane of the image) provides a tension force component that pulls the EZPV meta-module 1502 toward the mounting surface and so tends to secure the EZPV meta-module 1502 against wind lift.

The number of upper-edge connections 1506, 1508 is depicted as two in FIG. 15A, but in various embodiments may be any number greater than zero; likewise, the number of lower-edge connections 1516, 1518 may in various embodiments be any number greater than zero. The number of solar panels comprised by the EZPV meta-module 1502 is depicted as four in FIG. 15A but in various other embodiments may be any number greater than zero. Load bars 1504 and 1514 are illustrated in FIG. 15A; a similar effect can be achieved by the use of load points (connecting directly to 1510, 1512, 1520, 1522).

In various embodiments, either the first load bar 1504, the second load bar 1514, or both may be omitted in favor of anchor weights integrated with the supportive framework of the EZPV meta-module 1502; or, the anchor connectors 1510, 1512 may be omitted in favor of anchor weights connected to the load bars 1504, 1514. Anchor weights stabilize the position of the EZPV system 1500A by friction and/or by balancing of weight loads (e.g., on both sides of a peaked roof), rather than by clamping or penetration of a mounting surface.

FIG. 15B depicts an embodiment of an illustrative planar, rectangular EZPV meta-module installation (i.e., EZPV meta-module) 1500B mounted in a landscape orientation, i.e., with a longer edge of the EZPV meta-module 1502 more elevated than any other part thereof. The system 1500B and the conventions of its portrayal in FIG. 15B are similar to those of system 1500A of FIG. 15A, except that for an EZPV meta-module 1502 of a given size and form, the load bars 1524, 1526 are more closely spaced than in FIG. 15A, and more panel-to-bar connectors (e.g., 1528, 1530) and anchoring devices (e.g., 1532) are required. Given the use of comparable connecting and anchoring hardware, the configuration of FIG. 15B will tend to be more resistant to wind and other loads and may be preferable in conditions subject to such loads (e.g., an unusually windy or snowy location).

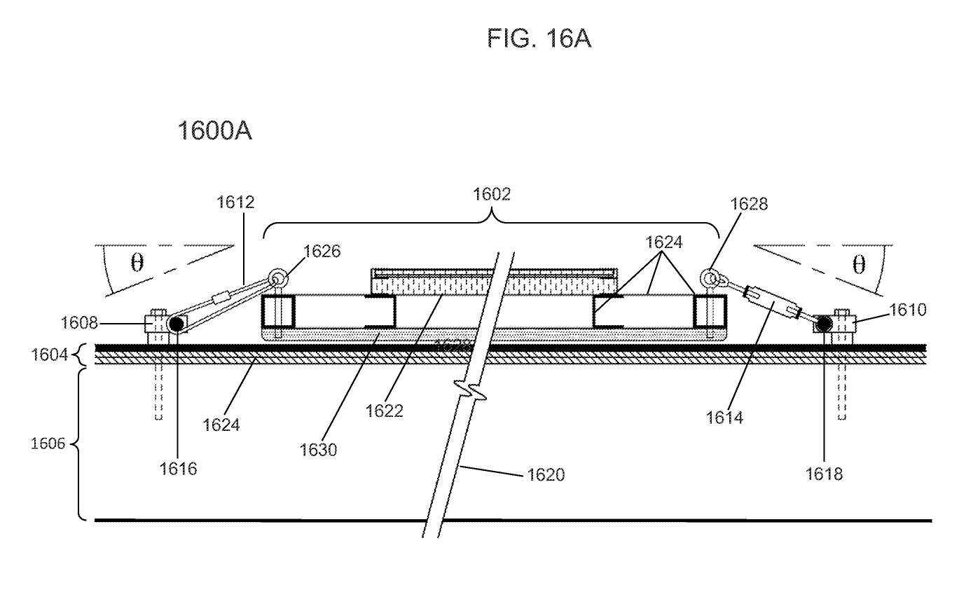

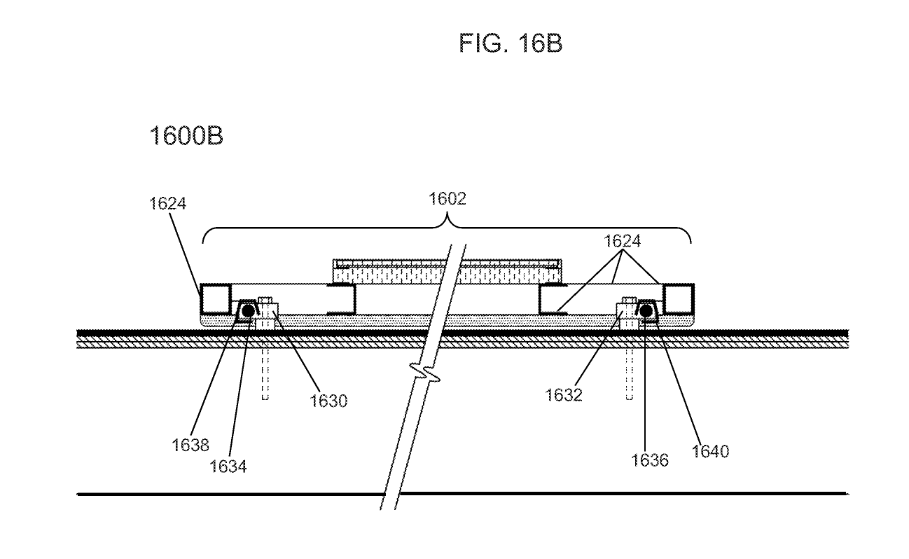

FIG. 16 is a cross-sectional schematic depiction of portions of an illustrative EZPV installation 1600A. The installation 1600A is similar to that depicted in FIG. 15A and FIG. 15B. The installation 1600A comprises an EZPV meta-module 1602, a planar installation surface (roof) comprising surface layers 1604 and a substructure (e.g., rafters) 1606, roof-penetrating anchors (e.g., anchors 1608, 1610), tensile-load-bearing connectors (e.g., connectors 1612, 1614), and load bars (e.g., load bars 1616, 1618). An omission symbol 1620 indicates that the portions of the drawing to the immediate left and right of the omission symbol 1620 could be extended, in a drawing of system 1600A having more realistic dimensions. The EZPV meta-module 1602 comprises a set of solar panels 1622, a metal supportive frame 1624 to which the solar panels 1622 are attached by means (e.g., bolts, clamps) not depicted, a number of connection points 1626, 1628 (e.g., eyelets, as depicted in FIG. 16A), and runners 1630 (e.g., plastic runners consisting of plastic lumber) that are connected to the underside of the metal frame 1624 and that rest upon the surface layers 1604 of the installation surface. The runners 1630 (e.g., made of plastic) may serve to lift the frame above standing seams by acting only in the direction parallel to the standing seams, may serve to prevent roof damage (e.g. scratching of metal roof paint) by acting as a softer surface between the rooftop and frame, may prevent galvanic and other potential corrosion by acting as a non-metal barrier between a metal roof and metal frame, may be higher friction than the frame material and thus prevent potential side-to-side sliding of the EZPV meta-module 1602, may prevent bowing of the EZPV meta-module 1602, and may serve to distribute the weight of the EZPV meta-module 1602 over most or all of the area of contact between the runners and the mounting surface 1604. A first type of tensile connector 1612 is preferably passive, i.e., can bear a tensile load exerted upon it by an anchor 1608 and eyelet 1626. A second type of tensile connector 1614 is preferably active, i.e., can be shortened (e.g., as a turnbuckle) to exert a tensile load on the anchor 1610 and the eyelet 1628. This tension is transmitted through the metal frame 1624 to the eyelet 1626, tensile connector 1612, and anchor 1608. Both the passive tensile connectors (e.g., connector 1612) and the active tensile connectors (e.g., connector 1614) are at an angle θ with respect to the installation surface, said angle being between 0 degrees and 90 degrees and preferably between 15 degrees and 40 degrees. In various other embodiments, the passive tensile connectors and active tensile connectors may be at different angles (i.e., θ₁ and θ₂), constrained similarly to depicted angle θ, with respect to the installation surface. By exerting upon the EZPV meta-module 1602 tensile forces acting toward the installation surface, the tensile connectors (e.g., connectors 1612, 1624) cause the EZPV meta-module 1602 to press against the installation surface with a force greater than could be caused by the weight of the EZPV meta-module alone. The EZPV meta-module is thus better secured against displacing forces, e.g., wind loads.

The anchors 1608, 1610 may be connected to the load bars 1616, 1618 in such a manner that they can be easily slid up and down the length of the load bar prior to attachment to the roof. The attachment of the anchors 1608, 1610 to the roof (e.g. by tightening a bolt such as a lag bolt) may be configured in such a way as to grip the load bar 1616, 1618 in the anchor 1608, 1610, preventing further movement. In this way, the relative location of the anchor 1608, 1610 upon the load bar 1616, 1618 may be easily varied during installation to accommodate different spacings (e.g. between roof rafters, between standing seams) and then fixed in place easily during the completion of the installation process and for the lifetime of the installation.

FIG. 16B is a cross-sectional schematic depiction of portions of an illustrative EZPV installation 1600B that is similar in most respects to the installation 1600A of FIG. 16A. The installation 1600B differs from the installation 1600A in that the EZPV meta-module frame 1624 is secured to the installation surface by spring-loaded clamps or eyelets 1638 (or a similar locking mechanism for mechanically securing the frame to the load bars 1634, 1636) that are connected to load bars 1634, 1636; such connection may be made by, for example, pushing the frame and clamps onto the load bar until a lever mechanism in the clamps retracts to allow the load bar into an opening in the frame; when the bar is fully within opening, the lever mechanism snaps back (via spring) to secure the bar. Removal of the bar from the frame from such an illustrative coupling mechanism can be achieved via manual compression of the lever mechanism (against the spring action). In FIG. 16B, the load bars 1634, 1636 are attached to penetrating anchors 1630, 1632. The load bars are spaced at a given distance such that they match the mating openings in the spring-loaded clamps internal to the EZPV meta-module frame 1624.

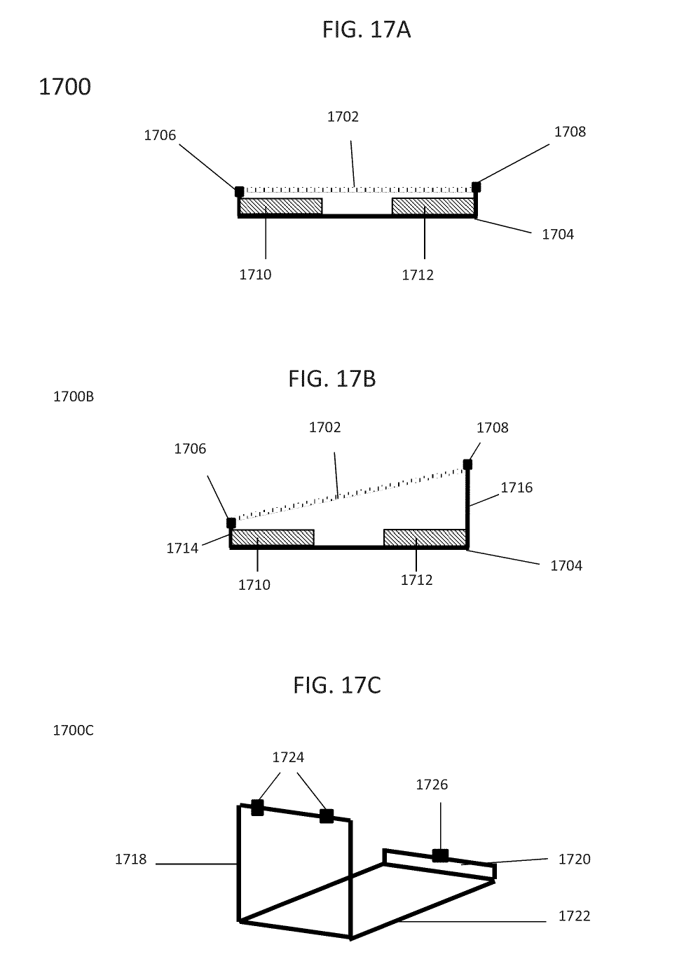

FIG. 17A is a schematic depiction of portions of an illustrative embodiment in which a meta-module PV system 1700A is ballast-mounted, i.e., where the EZPV supportive frame is anchored using a ballast mount. The EZPV pre-wired and mounted solar panels 1702 is mounted to ballast frame 1704 using mounts 1706 and 1708. The mounts 1706, 1708 may be quick-mount mechanisms for field connection or may be factory mounted using conventional methods such as bolting or welding. The pre-wired and mounted solar panels 1702 may comprise their own frame which may be quick-mounted to the ballast frame 1704 or the ballast frame may comprise the frame for the pre-wired and mounted solar panels. In this cross-sectional depiction, only two mounts 1706, 1708 are shown, but in various embodiments more may be used. Ballast 1710, 1712 is placed on ballast frame 1704. Ballast 1710, 1712 may be concrete, sand bags, or other material. Ballast frame 1704 may have high-friction coating (e.g. Neoprene, rubber, high friction paint) on underside which improves friction between frame 1704 and the installation surface (e.g., roof, not depicted). Ballast 1710, 1712 provides sufficient weight to prevent sliding of unit and/or flipping of unit in high winds (e.g., up to 160 mph). The whole system 1700 may be lifted into place at once or in other embodiments, the ballast frame 1704, ballast 1710, 1712, and pre-wired and mounted solar panels 1702 may be assembled on the rooftop via fast connects and setting of ballast in recessed locations. A wind deflector (not shown) maybe installed onto the ballast frame 1704 in order to reduce wind loading. The ballast frame 1704 may or may not include a seismic anchor (not shown).

FIG. 17B shows an embodiment of the invention where a ballast mount is used to support the EZPV meta-module at an angle to the horizontal. EZPV meta-module frame 1702 is mounted to ballast frame 1704 using mounts 1706, 1708. The mounts 1706, 1708 may be quick-mount mechanism for field connection or may be factory mounted using conventional methods such as bolting or welding. In this cross-sectional depiction, only two quick-mount mechanisms are shown, but more may be used. Ballast 1710 and 1712 is placed on ballast frame mount 1708. Ballast may be concrete or other material. Legs 1714, 1716 of ballast mount can be made at different heights (and/or extensible) to allow for different tilt angles. The ballast frame 1704 may have high-friction coating on its underside, in contact with the installation surface. Ballast 1710, 1712 provides sufficient weight to prevent sliding and/or flipping of unit in high winds (e.g., up to 160 mph). The whole system 1700B may be lifted into place at once or in other embodiments, the ballast frame 1704, ballast 1710, 1712, and pre-wired and mounted solar panels 1702 may be assembled on the rooftop via fast connects and setting of ballast in recessed locations. A wind deflector (not shown) may or not be installed onto the ballast mount 1704 in order to reduce wind loading. The ballast mount 1704 may or may not include a seismic anchor (not shown).

FIG. 17C shows an embodiment of a ballast mount frame 1700C (e.g., ballast mount frame 1708 in FIG. 17A and FIG. 17B). The ballast frame 1700C consists of two vertical U-sections 1718, 1720 connected to a rectangular horizontal section 1722. The heights of the vertical sections 1718, 1720 can be varied (e.g., by making the vertical members of the U-sections 1718, 1720 extensible, or by manufacturing vertical members of various heights) to provide different solar panel tilt angles. The rectangular horizontal section 1722 may comprise a tray for receiving ballast and may have high-friction coating on its underside, which is preferably in contact with the installation surface. A number of quick-mount mechanisms 1724, 1726 may be used to secure a EZPV meta-module to the ballast mount frame 1700C. Width of ballast mount (i.e., width of horizontal section 1722) and tilt angle are preferably optimized to maximize sunlight impinging on solar cells.

Ballast-mounted EZPV modules (e.g., those depicted in FIG. 17A and FIG. 17B) may be installed on the following roofing materials, among others: ethylene propylene diene monomer (M-class) rubber, thermoplastic polyolefin, polyvinyl chloride, modified bitumen, and built-up roof and tar and gravel.

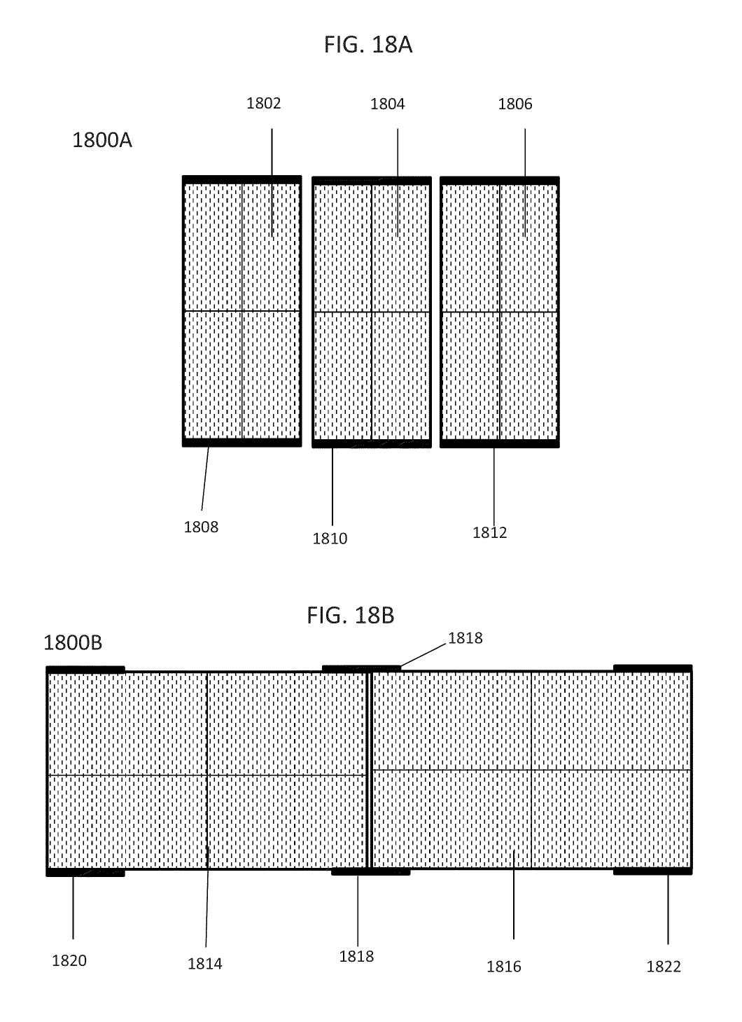

FIG. 18A is a schematic top-down depiction of an illustrative embodiment of a EZPV meta-module system 1800A in which a number of EZPV meta-modules (1802, 1804, 1806) connected to ballast mount frames (1808, 1810, 1812) and are aligned in a row. In this embodiment, each ballast-mount frame (not shown) and the EZPV meta-module installed therein is independent of every other, i.e., no mechanical connection exists between each frame-module pair. Each frame-module pair may be lifted in its entirety into place on the installation surface.

FIG. 18B shows an illustrative embodiment of a EZPV meta-module system 1800B in which two EZPV meta-modules 1814, 1816 are installed into a first ballast mount frame 1818. Meta-module 1814 is also supported by a second ballast mount frame 1820 and meta-module 1816 is also supported by a third ballast mount frame 1822. In the installation of the system 1800B, ballast mount frames 1818, 1820, and 1822 may be arranged on roof and EZPV meta-modules lifted into place. In this manner, reduce framing materials may be used for certain ballast mount applications. More than 2 EZPV frames may be connected in this manner to form a long row of modules.

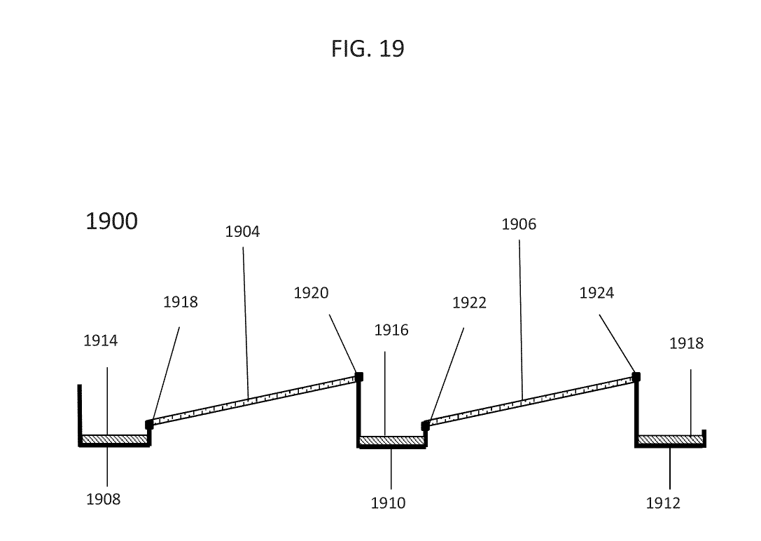

FIG. 19 is a schematic cross-sectional depiction of portions an illustrative embodiment in which ballast mounts are used to connect multiple rows of EZPV meta-modules. In various embodiments, EZPV meta-modules may be tilted, as depicted in FIG. 19. In FIG. 19, a first EZPV meta-module 1904 is connected to ballast mounts 1908 and 1910 by quick-mount mechanisms 1918 and 1920, and a second EZPV meta-module 1906 is connected to ballast mounts 1910 and 1912 by quick-mount mechanisms 1922 and 1924. Ballast mount 1910 provides a mechanical (e.g., load-sharing) connection between EZPV meta-modules 1904 and 1906. Ballast 1914, 1916, 1918 is placed in ballast mounts 1908, 1910, 1912. The ballast mounts 1908, 1910, 1912 may be similar or identical to the ballast mount 1700C depicted in FIG. 17C.

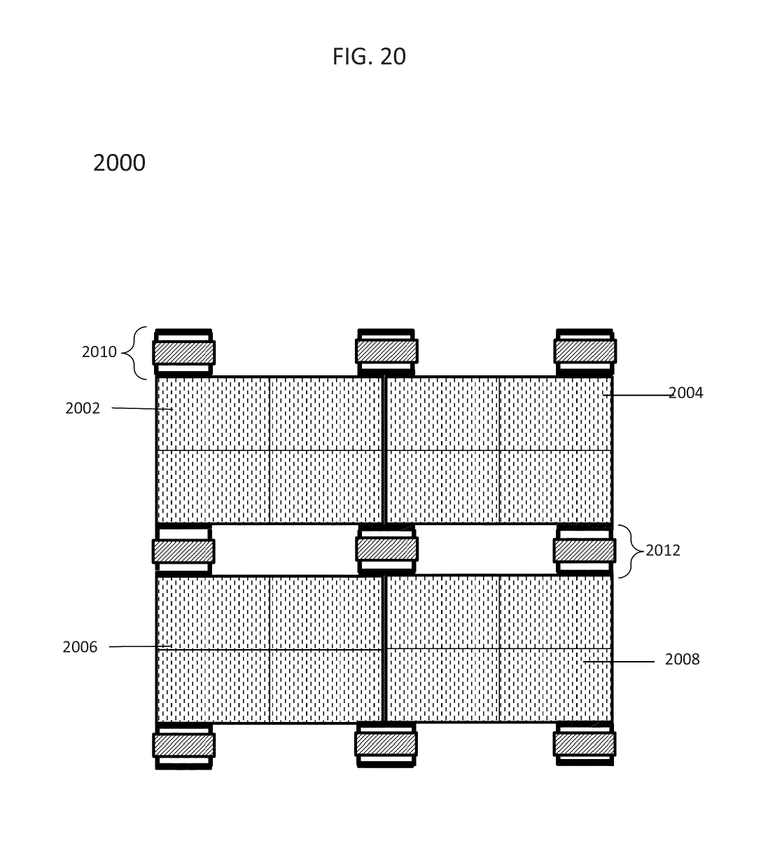

FIG. 20 is a schematic top-down depiction of portions an illustrative system 2000 in which ballast mounts are used to connect multiple rows and columns of EZPV meta-modules. In FIG. 20, four EZPV meta-modules 2002, 2004, 2006, 2008 are connected to nine ballast mounts (e.g., mounts 2010, 2012). The gridlike arrangement depicted in FIG. 20 has two rows (a first row comprising EZPV meta-modules 2002, 2004 and a second row comprising EZPV meta-modules 2006, 2008) and two columns (a first column comprising EZPV meta-modules 2002, 2006 and a second column comprising EZPV meta-modules 2004, 2008): this regular grid-like structure may, in various embodiments, either be reduced (e.g., by the omission of one or more of the EZPV meta-modules 2002, 2004, 2006, 2008) or be extended to any number of rows and columns, and to any dimension independently in its various rows and columns. Moreover, in various embodiments comprising a grid of three or more columns and three or more rows, omission of one or more EZPV meta-modules from the grid enables the creation of “holes” in the grid. Larger grids will tend to accommodate the creation of larger and/or more numerous holes. Irregular extension of rows and columns, as well as the creation of grid holes of whatever size, may be preferable whenever the grid is to be extended over a large installation surface interrupted by objects (e.g., air-conditioning units, antennae, vent stacks).

FIG. 21 is a schematic cross-sectional depiction of portions of an illustrative EZPV meta-module system 2100 in which an EZPV meta-module (2102) is secured to a flat (or near-flat, e.g., approximately 0 to 5 degree) surface using low-slope mounts 2106 and 2108. A low-slope mount could be (but is not restricted to being) a low-slope mount such as the QBase composition mount sold by Quick Mount PV Inc. having a principal place of business at 2700 Mitchell Dr., Bldg. 2, Walnut Creek, Calif., 94598. Low-slope mounts may be used on (but are not restricted to use upon) a built-up asphalt roof or single-ply membrane roof. Low-slope mounts may be of different heights to allow the EZPV meta-module 2102 to be tilted towards the sun. Plastic runners similar to runner 1630 of FIG. 16A (not depicted) may be comprised by the system 2100 in order to support and distribute the weight of the EZPV meta-module 2012.

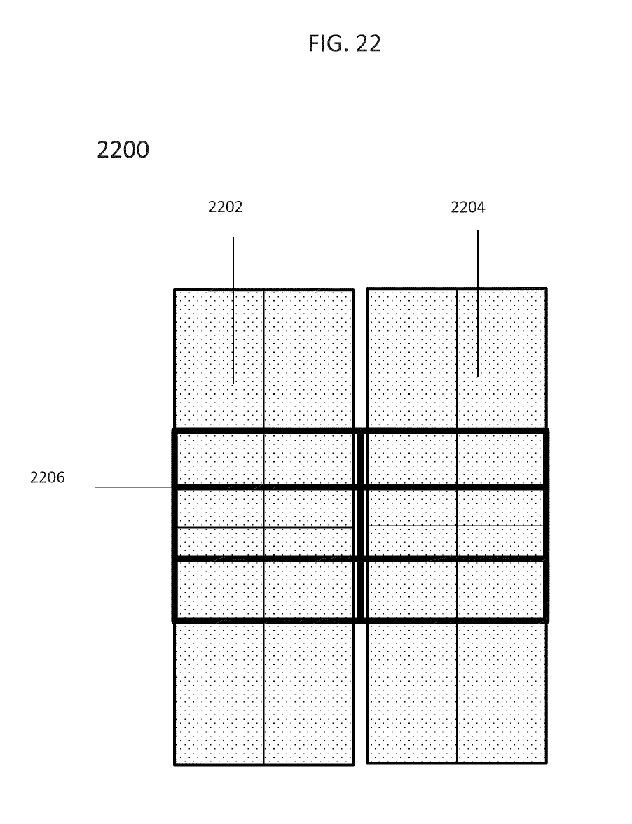

FIG. 22 is a schematic top-down depiction of an illustrative EZPV meta-module and base frame assembly 2200 suitable for pole mounting. Two planar, rectangular panel meta-modules 2202, 2204 that each have a width allowing transport by truck (e.g., less than 8.5 ft wide) in one dimension and longer length (e.g., 16 feet) in the other dimension are quick-mounted to a planar base frame 2206. The base frame 2206 additionally may have width allowing transport by truck (e.g., less than 8.5 ft wide) in one dimension and longer length (e.g., 16 feet) and may be similar in size to an individual EZPV meta-module and preferably comprises hardware (not shown) for quick attachment to a pole (not shown). The three pieces 2202, 2204, 2206 may be factory assembled, with additional assembly of electrical wiring and electrical and electronic components (not shown; e.g., microinverters), and trucked to the installation site. The pieces may be lifted into place via a lifting mechanism (e.g. boom truck, crane, forklift) and the entire installation may be completed in less than one hour. In various embodiments, the entire installation may completed in less than two hours, less than four hours, and less than eight hours.

Assembly 2200 also comprises Quick-connect connectors (e.g., 2208) enabling the EZPV meta-modules 2202, 2204 to be connected readily by inter-module wiring 2210 (e.g., in series, as depicted in FIG. 22), and by further wiring 2212 to a Quick-connect connector 2214 on a solar interconnection box 2216. The solar interconnection box 2204 may contain an inverter; or, microinverters (not shown) may be integrated with the EZPV meta-modules 2202, 2216. The solar interconnection box 2216 may contain disconnect boxes, electronic devices for data collection or control, a solar meter, an inverter, and other devices; it may be connected to other EZPV meta-module systems, either pole-mounted or otherwise mounted. In FIG. 22 and in various other embodiments, the solar interconnection box 2216 is connected to a utility service meter 2218 and thus may supply power to various loads (e.g., building loads, a grid). Electrical arrangements similar to those depicted and described for assembly 2200 (e.g., Quick-connect chaining of EZPV meta-modules; Quick-connect interface to a solar interconnection box; connection of solar interconnection box may be made for any of the assemblies comprising EZPV meta-modules depicted herein, as well as others not depicted, even when their presence is not explicitly depicted or discussed.

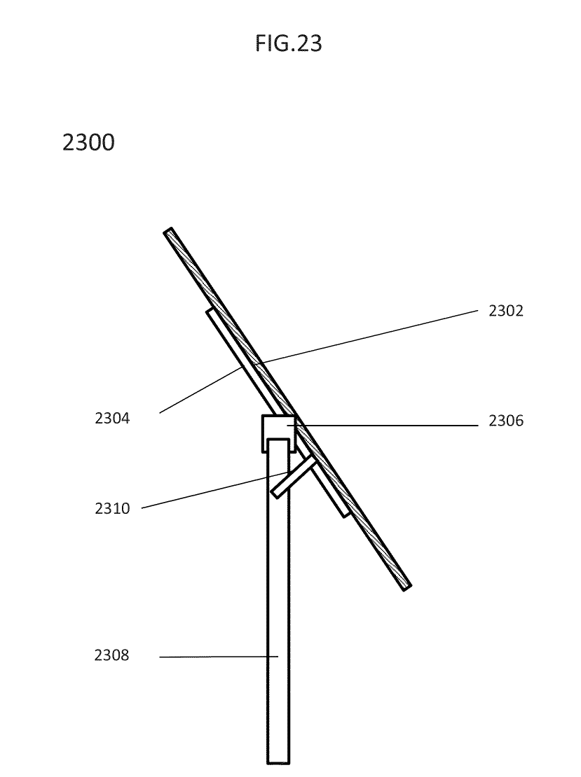

FIG. 23 is a schematic, cross-sectional depiction of an illustrative pole-mounted EZPV meta-module system. An EZPV meta-module 2302 (or multiple EZPV meta modules) is connected to base mount 2304, which is similar to base mount 2206 in FIG. 22. Base mount 2304 is connected by a quick-mount mechanism 2306 to a pole 2308 that may be either extensible or fixed in length. The EZPV meta-module 2302 and base frame 2304 additionally may have width allowing transport by truck (e.g., less than 8.5 ft wide) in one dimension and longer length (e.g., 16 feet) and may be similar in size. The layout may be similar to that depicted in FIG. 22. The EZPV meta-module 2202 and base frame 2304 may be factory assembled and trucked to the installation site. The pieces may be lifted into place via a lifting mechanism (e.g. boom truck, crane, forklift) and the entire installation may take less than one hour. Seasonal adjustability for maximizing energy production may be provided by allowing for several tilt-angle settings and may be operated by a single individual. For example, mount 2306 may swivel, and tilting may be achieved by various mechanisms, e.g., an extendable/retractable pole 2010 which extends from the pole 2308 to the base mount 2304. In other embodiments, the system may be capable of automatic one or two-axis tracking. The pieces of assembly 2300 may be lifted into place via a lifting mechanism (e.g., boom truck, crane, forklift) and the entire installation may be completed in less than one hour. In various embodiments, the entire installation may be completed in less than two hours, less than four hours, and less than eight hours. In various embodiments, placement of the pole 2308 may require sinking of a hole and creation of a concrete footing: in various other embodiments, pole 2308 may be stably supported by buttress supports and/or a footing weight and/or other arrangements enabling the rapid installation of the pole 2308.

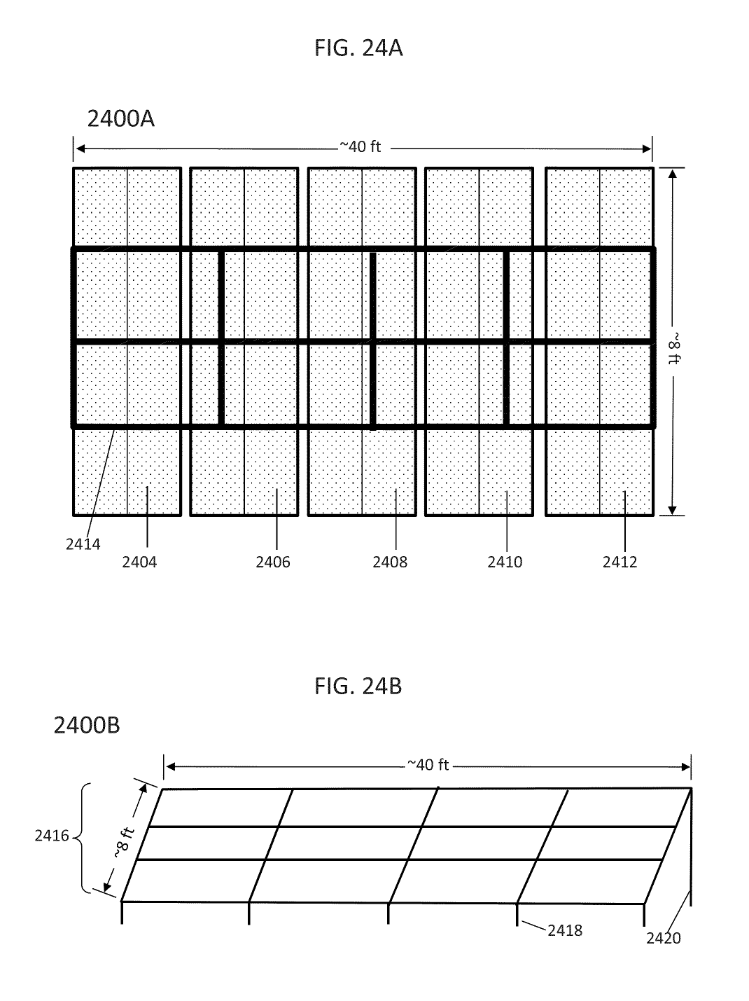

FIG. 24A is a top-down schematic depiction of an illustrative EZPV meta-module and base frame assembly 2400A suitable for field mounting. In an embodiment of the invention, multiple planar, rectangular EZPV meta-modules 2404, 2406, 2408, 2410, 2412 are mounted onto a field-mount base frame 2414. The EZPV meta-modules 2404, 2406, 2408, 2410, 2412 may have width allowing transport by truck (e.g., less than 8.5 ft wide) in one dimension and longer length (e.g., 16 feet), and comprise hardware (not shown; e.g., clamps, clasps, hooks, bayonet mounts) enabling their quick mounting to a base frame 2414. The base frame 2414 may have width allowing transport by truck (e.g., less than 8.5 ft wide) in one dimension and much longer length (e.g., flatbed truck bed length of approximately 48 feet), and may have hinged or separate legs (not shown) that enable it to lie flat for transport. The dimensions and number of EZPV meta-modules on the base frame specified for FIG. 24A are illustrative only. The pieces 2404, 2406, 2408, 2410, 2412, 2412 may be factory assembled and trucked to the installation site. The pieces may be lifted into place via a lifting mechanism (e.g. boom truck, crane, forklift) for installation and the entire installation may take less than one hour. In various embodiments, the entire installation may be completed in less than two hours, less than four hours, and less than eight hours.

FIG. 24B is a schematic depiction of an illustrative base frame assembly 2400B suitable for mounting on an extensive, approximately level installation site (e.g., on the ground). The base frame 2416 may have width allowing transport by truck (e.g., less than 8.5 ft wide) in one dimension and much longer length (e.g., flatbed truck bed length of approximately 48 feet), and may have legs (e.g., 2418, 2420) that support the base frame 2416 and orient at a desired tilt angle. The legs 2418, 2420 may be hinged or separable to enable the frame 2416 to lie flat for transport. The legs 2418, 2420 may be extensible in order to allow installation over a range of desired tilt angles.

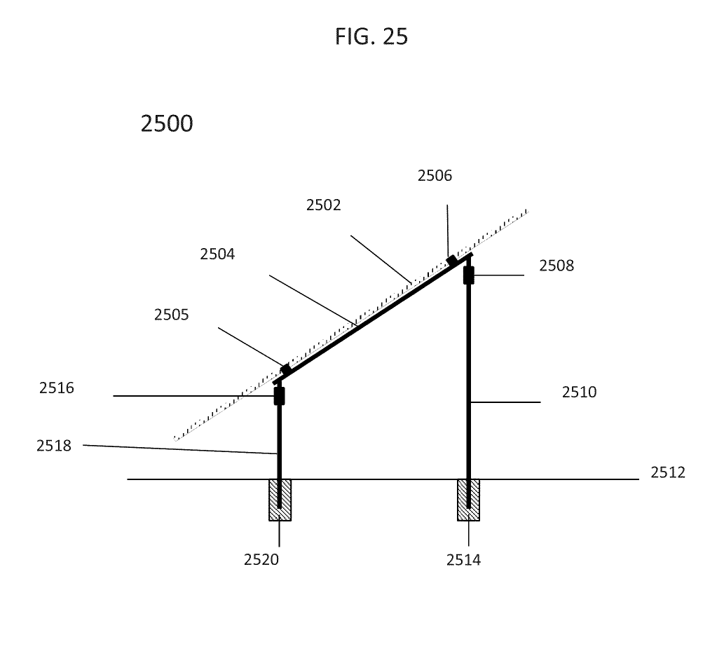

FIG. 25 is a schematic cross-sectional depiction of an illustrative EZPV meta-module assembly 2500 comprising a field-mounted base frame (e.g., the base frame 2416 of FIG. 24B) connected to EZPV meta-modules. In this embodiment, EZPV meta-module 2502 is connected to a base frame 2504 using quick mounts 2505, 2506. A back leg 2510 of the base frame 2504 can be locked in place by a locking mechanism 2508 and fixed in the ground 2512 by a footing 2514. A front leg 2518 of the base frame 2504 can be locked in place by a locking mechanism 2518 and fixed in the ground 2512 by a footing 2520. There may be one, two, or more front legs and one, two, or more back legs. The footings (e.g., footings 2514, 2520) may comprise poured concrete, helical augurs, ballast plates, or other ground-anchoring mechanisms, and/or may be stabilized by buttresses and/or anchoring weights. In assembly 2500 and other EZPV meta-module assemblies, both depicted herein and not depicted herein, the length of legs (e.g., legs 2510, 2518) can be varied (e.g., by telescoping, sectional extension, or other means) to provide an desired tilt angle for the EZPV meta-module 2502; the legs (e.g., legs 2510, 2518) may be retractable for storage and transport and extended during installation. In this and various other base-frame configurations depicted herein, additional members (e.g., cross-pieces), not depicted, may be attached to portions of the base frame in order to increase resistance to environmental force loads (e.g., wind, snow loads) In various embodiments, EZPV meta-modules (not shown) attached to various base frames and base plates, both depicted herein and not depicted herein, may comprise hardware (not shown; e.g., clamps, clasps, hooks, bayonet mounts) enabling their quick mounting to the base frame 24504.

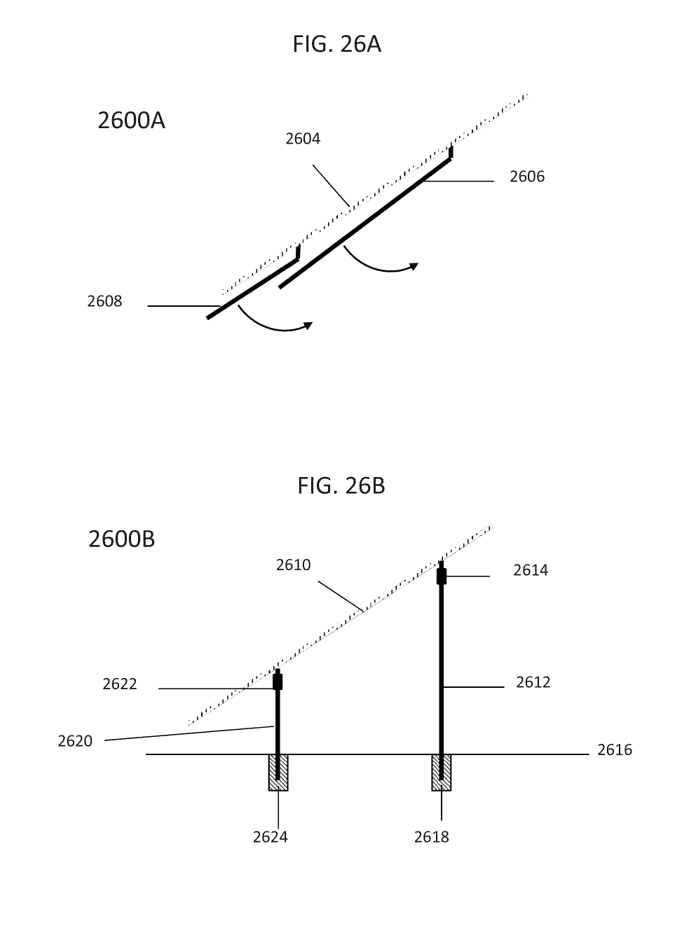

FIG. 26A is a schematic cross-sectional depiction of portions of illustrative field EZPV meta module system 2600A suitable for field mounting, where legs 2606, 2608 are directly connected to the EZPV module 2604. The legs 2606, 2608 can be retracted for storage and transport and extended during installation. In this and various other base-frame configurations depicted herein, additional members (e.g., cross-pieces), not depicted may be attached to portions of the base frame in order to increase resistance to environmental force loads (e.g., wind, snow loads).

FIG. 26B is a schematic cross-sectional depiction of an illustrative EZPV meta-module system 2600B comprising a field-mounted base frame (e.g., the base frame 2416 of FIG. 24B) connected to EZPV meta-modules. In the embodiment of FIG. 26B, EZPV module 2610 is directly connected to a number of support legs (e.g., legs 2612, 2622). The legs 2612, 2620 are locked in extended position by locking mechanisms 2614, 2622 (e.g., screw tighteners). The legs 2612, 2620 are secured in ground 2616 by footings 2618, 2624, which may be as described for the footings 2520, 2514 of FIG. 25.

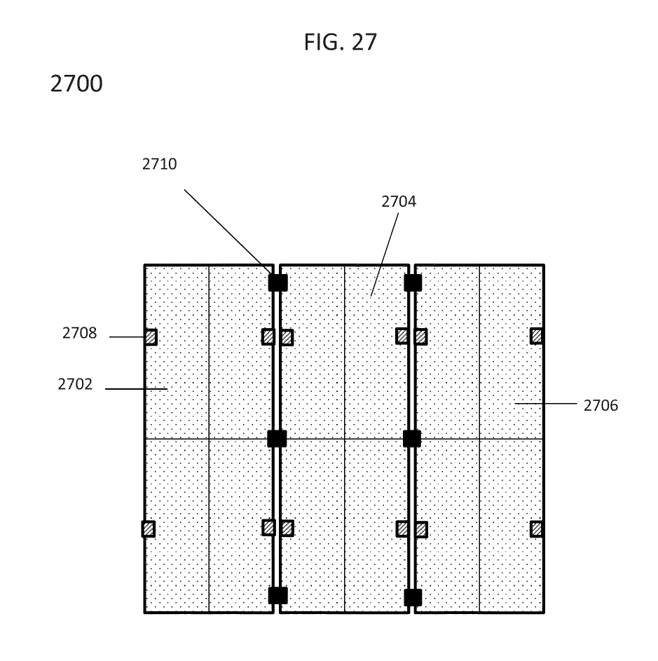

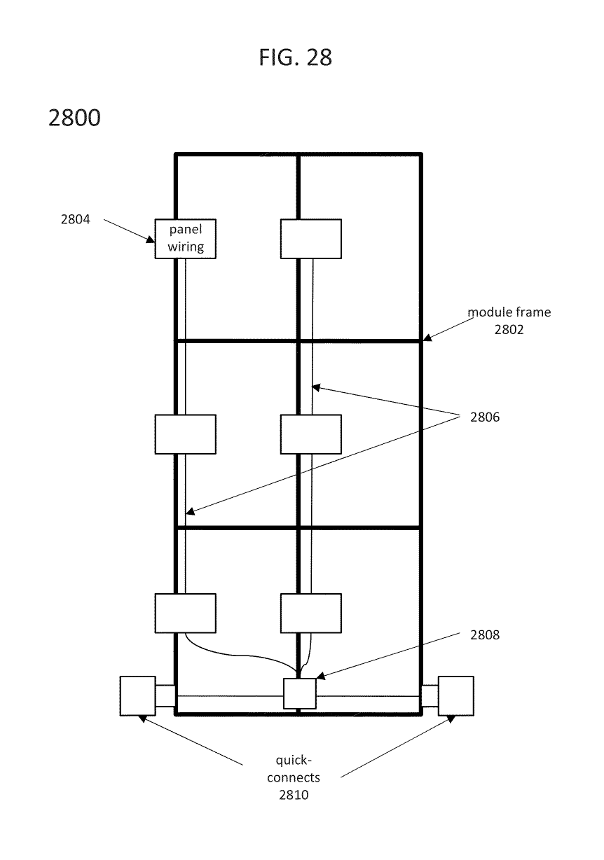

FIG. 27 is a schematic top-down depiction of an illustrative EZPV meta-modules assembly 2700 with support legs for field mounting, in which EZPV meta-modules similar to those described in FIGS. 26A and 26B have been mechanically interconnected to increase structural support. In FIG. 27, EZPV modules 2702, 2704, 2706 with attached legs (e.g., leg 2708, depicted in cross-section), are connected together by quick-mount mechanisms (e.g., connector 2710).

FIG. 28 is a top-down schematic depiction of portions of an EZPV meta-modules assembly 2800 comprising a layout of electrical connections on a meta-module frame 2802. Each solar panel (not depicted) may be connected to individual wiring components 2804, each of which could comprise a variety of systems, possibly including micro-inverters and/or optimizers. Wires 2806 connect panels to a common module wiring system 2808, which is connected to Quick-connect connectors 2810. In assembly 2800 and in various other embodiments, both depicted herein and not depicted herein, Quick-connect connectors (e.g., connectors 2810) may comprise a waterproof multi-prong plug connector, or multiple single-plug connectors (e.g., the CS-MS waterproof electrical connectors sold by SeaCon Inc. having a principal place of business at Seacon House, Hewett Road, Gapton Hall Industrial Estate, Great Yarmouth, Norfolk, NR31 ORB, UK; or, standard MC4 solar connectors; or, other), or other plug-and-socket type connectors. The Quick-connect connectors 2810 may be used to connect to more EZPV meta-module assemblies, to a solar interconnection box, or directly to the electrical grid. The wiring between Quick-connect connectors may be of a higher current capacity (larger diameter) than the wires 2806 within the meta-module, in order to allow for the connection of multiple meta-modules resulting higher current levels through the wiring of the Quick-connect connectors 2810. The design of assembly 2800 speeds manufacturing of meta-modules by integrating the electrical layout with the module frame 2802, enabling meta-modules to be wired up during the manufacturing process and connected during installation by quick-connects 2810. Electrical wiring may include wiring of power connections (e.g. DC positive and neutral wires, AC 240 V wiring, AC three-phase wiring) and grounding connections (e.g. equipment grounding of solar panel frames, metallic meta-module frame, microinverter metallic cases). In various embodiments, these electrical components include micro-inverters, intelligent optimizers, sensors, and other devices. The inverters are used to convert the direct current voltage produced by the solar panels to the alternating current voltage required by the electrical service and may be part of the meta-module (e.g. microinverters) or may be part of the solar interconnection box (e.g., string inverter).

The Quick-connect connectors (e.g., 2810) comprised by assembly 2800 enable the EZPV meta-module to be connected readily to other EZPV meta-modules (not shown) by inter-module wiring 2210 (not shown), and by further wiring 2812 to a Quick-connect connector 2814 on a solar interconnection box 2804. The solar interconnection box 2816 may contain an inverter; or, microinverters (not shown) may be integrated with the EZPV meta-module. The solar interconnection box 2816 may contain disconnect boxes, electronic devices for data collection or control, a solar meter, an inverter, and other devices; it may be connected to other EZPV meta-module systems (not shown), either pole-mounted or otherwise mounted. In FIG. 28 and in various other embodiments, the solar interconnection box 2816 is connected to a utility service meter 2218 and thus may supply power to various loads (e.g., building loads, a grid).

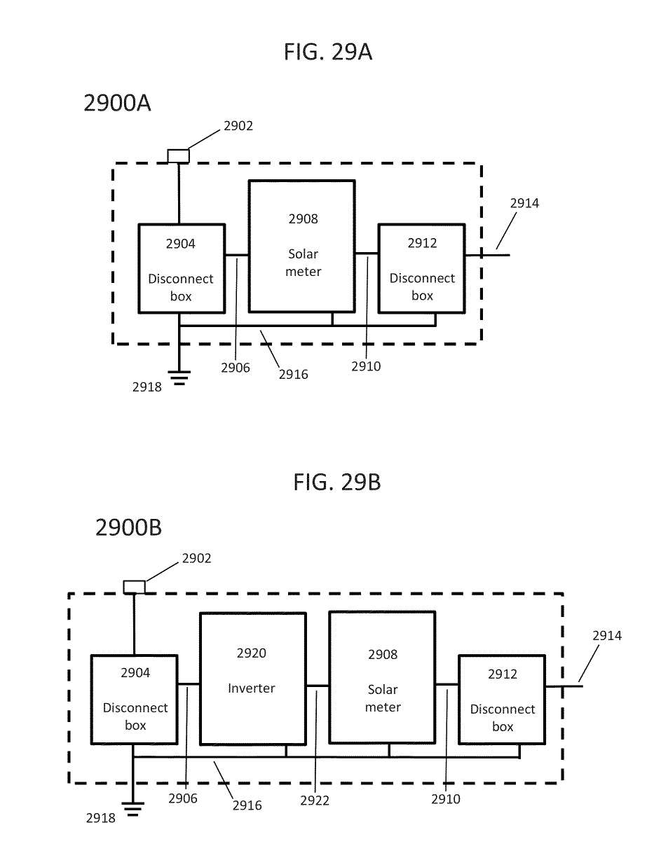

FIG. 29A depicts an illustrative pre-wired electrical assembly 2900A, herein also termed a “solar interconnection box,” for interfacing a solar array with building electrical mains according to one embodiment of the invention. The solar interconnection box 2900A comprises the following components: (1) a Quick-connect socket 2902 (or plug) that enables a preferably tools-free, rapid electrical connection to wiring (not shown) from a nearby (e.g., rooftop) installation comprising one or more EZPV meta-modules; (2) a first disconnect box 2904 that enables, at minimum, the manual operation of a switch that electrically connects or disconnects the Quick-connect socket 2902 and the electrical output wiring 2906 of the first disconnect box, and that in various embodiments may contain breakers or fuses and/or be capable of operation by remote control or by an internal program-controlled computer; (3) a solar meter 2908, i.e., electronic or electromechanical device at least capable of measuring the total energy supplied to it through the electrical wiring 2906 over a period of time, and in various embodiments also capable of measuring power, voltage, current, and/or other electrical properties of the signal received through wiring 2906; (4) solar meter output wiring 2910; (5) a second disconnect box 2912 similar to the first disconnect box 2904; (6) electrical output wiring 2914 that may be connected to a standard utility electric meter; and (7) internal connections internal connections of the first disconnect box 2904, solar meter 2908, and second disconnect box 2912 to a common ground conductor 2916 that can be connected externally to an appropriate earth ground 2918.

Assembly 2900A is appropriate for an installation where appropriate inversion (i.e., direct-current to alternating-current conversion) of the output of the solar array has been performed prior to the Quick-connect connection 2902, e.g., by micro-inverters integrated with the photovoltaic meta-module.

FIG. 29B depicts an illustrative pre-wired electrical assembly 2900B, herein termed a “solar interconnection box,” for interfacing a solar array with building electrical mains according to one embodiment of the invention. The solar interconnection box 2900B comprises the following components, which may be similar to similarly numbered components in FIG. 12A: (1) a Quick-connect socket 2902 (or plug); (2) a first disconnect box 2904 having output wiring 2906; (3) an inverter 2920 having electrical output wiring 2922; (4) a solar meter 2908; (5) solar meter output wiring 2910; (6) a second disconnect box 2912 similar to the first disconnect box 2904 and having electrical output wiring 2906; (7) electrical output wiring 2914 that may be connected to a standard utility electric meter; and (8) internal connections of the first disconnect box 2904, inverter 2920, solar meter 2908, and disconnect box 2912 to a common ground conductor 2916 that can be connected externally to an appropriate earth ground 2918.

Assembly 2900B is appropriate for an installation where appropriate inversion (i.e., direct-current to alternating-current conversion) of the output of the solar array has not occurred prior to the Quick-connect connection 2902. The inverter 2920 performs inversion of direct-current electrical power entering the assembly 2900B through the Quick-connect connection 2902, and produces appropriate (e.g., three-phase, 60 Hz) alternating-current electrical power at its output wiring 2922.

In both the assembly 2900A of FIG. 29A and the assembly 2900B of FIG. 29B, the solar meter 2908 allows the measurement and display and/or tele-reporting of energy generated by the solar installation, and possibly of other properties of the electrical output of the solar installation: this information may be employed variously, e.g., for research or for reporting to a state agency or utility to validate a claim for rebates or incentives. Because a number of EZPV meta-modules may be manufactured to be substantially identical, data collected from a number of installations may be analyzed to yield performance information on various metrics (efficiency, reliability, etc.) that is design-specific, i.e., independent of any particular site.

The Quick-connect connection 2902 permits rapid connection to a solar array during installation. Connecting the assembly 2900A of FIG. 29A or the assembly 2900B of FIG. 29B to the building meter box obviates the need for any wiring inside the building during installation. The assembly 2900A of FIG. 29A or the assembly 2900B of FIG. 29B is preferably pre-assembled in a factory, transported to the installation site of an EZPV meta-module solar system, and installed at the installation site in order to minimize on-site skilled labor, speed installation, and reduce defects. In various other embodiments (e.g., embodiments intended for municipalities not requiring dedicated metering of solar output), the solar interconnection box 2900A or 2900B could consist solely of a single disconnect box 2904 or of a first disconnect box 2904, inverter 2920, and second disconnect box 2912.

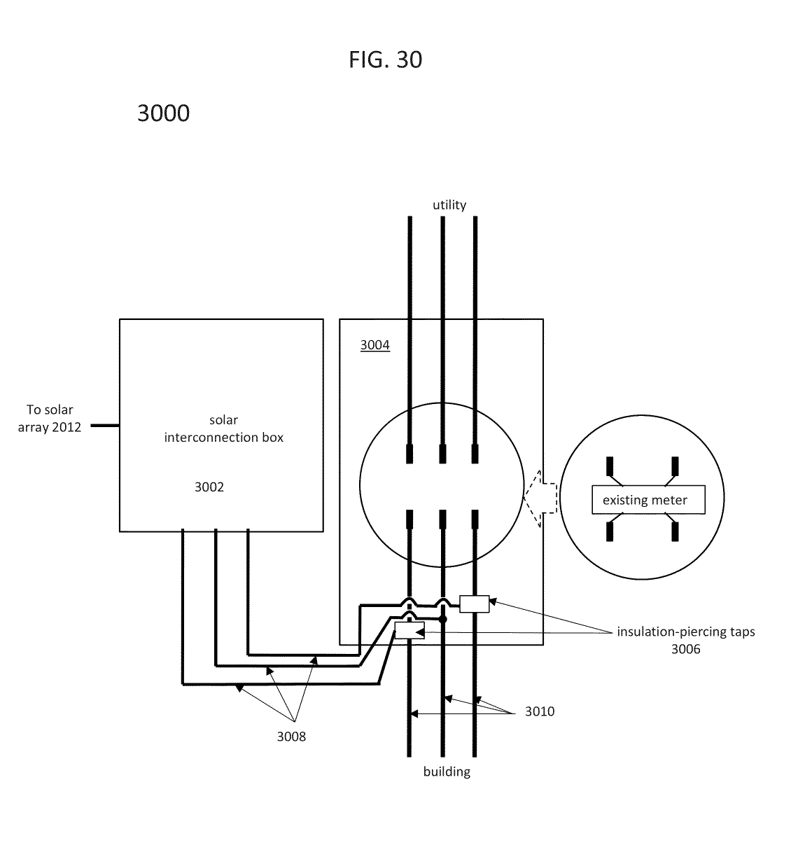

FIG. 30 schematically depicts one embodiment of an electrical assembly 3000 for connecting a solar power to the electrical grid. A solar interconnection box 3002 (e.g., a box similar to assembly 2900A of FIG. 29A) is wired into the building meter box 3004 by use of insulation-piercing tap connectors 3006 that connect wires from solar meter 3008 to building mains 3010. The neutral connector from the solar meter 3002 may be wired to the neutral wire of the building meter 3004 (typically without wire insulation) with a standard tap connection. Solar interconnection box 3002 is connected to the solar array (not shown) by a Quick Connect connector at point 3012. By using this type of tap at the building meter box 3004, installation time and cost may be reduced as compared with installations that require entry of the building and use of the internal building utility panel and breaker box.

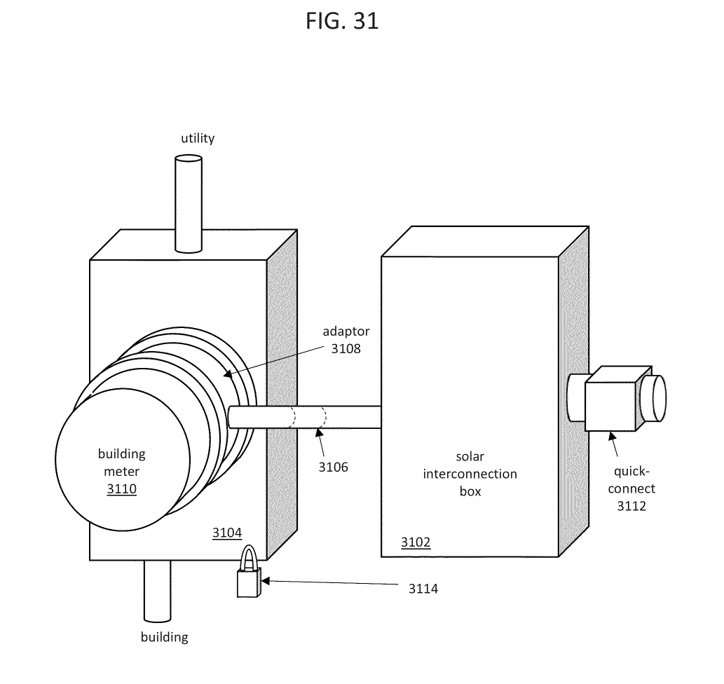

FIG. 31 depicts one embodiment of a pre-wired electrical system 3100 for rapid interfacing a solar array (not shown) with building electrical mains. Pre-wired solar interconnection box 3102 is wired into building meter box 3104 via conduit 3106, which communicates to pass-through adaptor 3108 that mounts between meter socket in building meter box 3104 and building net meter 3110. Pass-through adaptor 3108 enables the entirety of System 3100 to be pre-wired, as adaptor 3108 can be installed by detaching building meter 3110 from meter box 3104, attaching adaptor 3108 to meter box 3104, and attaching meter 3110 to adaptor 3108. A Quick Connect connector 3112 permits rapid connection to solar array during installation. System 3100 is secured by standard utility safety protections, including tamper-proof tags 3114 on each electrical meter.

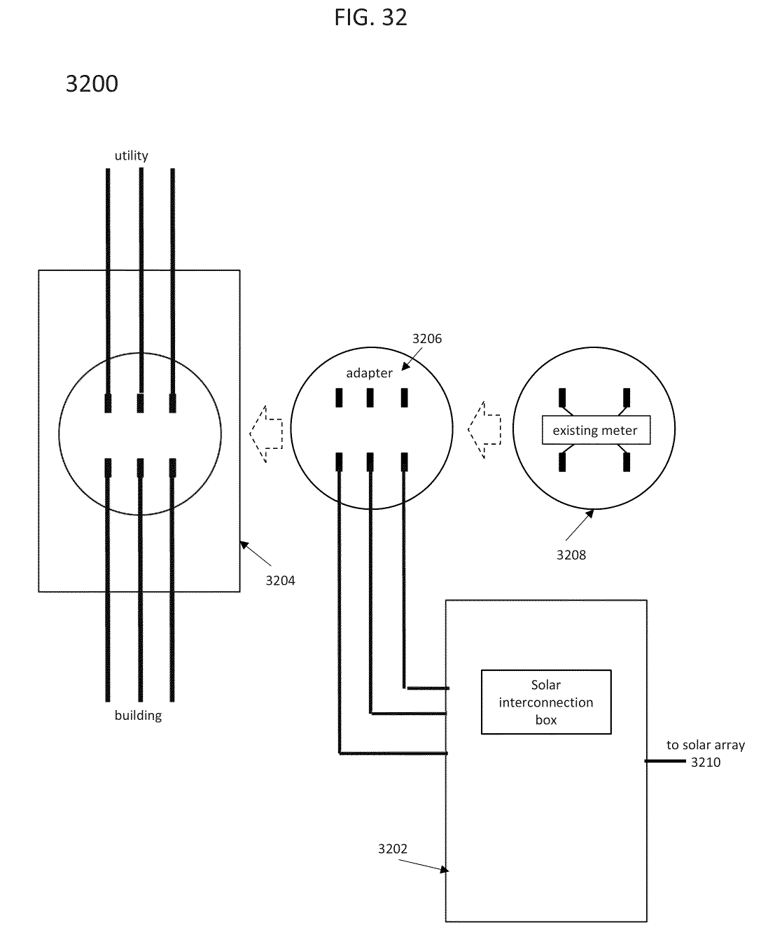

FIG. 32 schematically depicts the system described in system 3100, one embodiment of a pre-wired electrical system for interfacing solar array with building electrical mains. A pre-wired solar meter box 3202 is connected to the building meter box 3204 in parallel with the building electrical system via pass-through adaptor 3206 that mounts between meter socket in building meter box 3204 and building net meter 3208. The physical mounting of adaptor 3206 completes electrical connections between meter box 3204 and meter 3208, hence its designation as a pass-through. Solar meter box 3202 is connected to the solar array (not shown) by quick-connect at 3210. By using this type of quick connection at the building meter box 3204, installation time and cost may be reduced as compared with installations that require more wiring steps or require entry of the building and use of the internal building utility panel and breaker box.

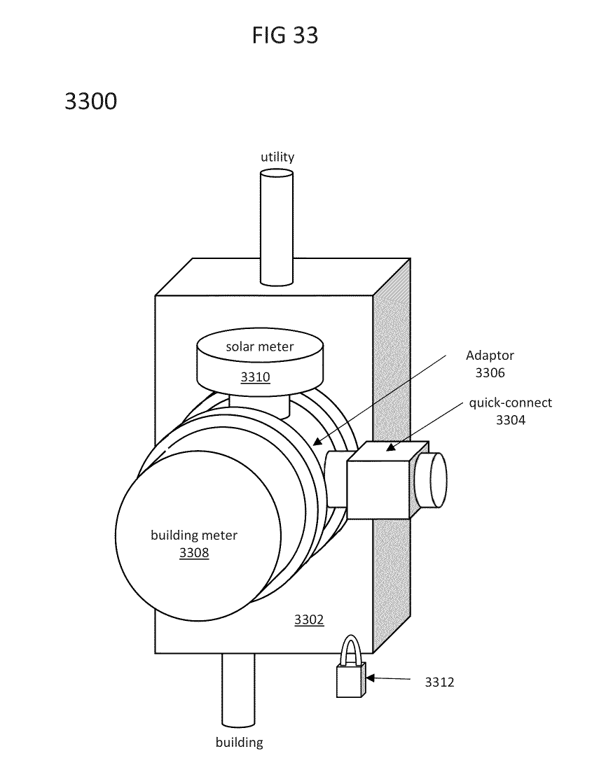

FIG. 33 depicts one embodiment of a pre-wired electrical system 3300 for interfacing solar array with building electrical mains. Solar array is connected to building meter box 3302 by means of quick-connect 3304, which communicates to pass-through adaptor 3306 that mounts between meter socket in building meter box 3302 and building net meter 3308. Pass-through adaptor 3306 enables the entirety of System 3300 to be pre-wired, as adaptor 3306 can be installed by detaching building meter 3308 from meter box 3302, attaching adaptor 3306 to meter box 3302, and attaching meter 3308 to adaptor 3306. Solar meter 3310 is integral to adaptor 3306, and is installed for the purpose of measurement and display of generated energy for incentive or rebate purposes. System 3300 is secured by standard utility safety protections, including tamper-proof tag 3312. Other safety devices such as breakers, fuses, or disconnects may be internal to the solar meter adaptor 3306 or quick connect 3304, allowing direct connection of the solar array via multi-conductor electrical cable to the quick connector adaptor 3304.

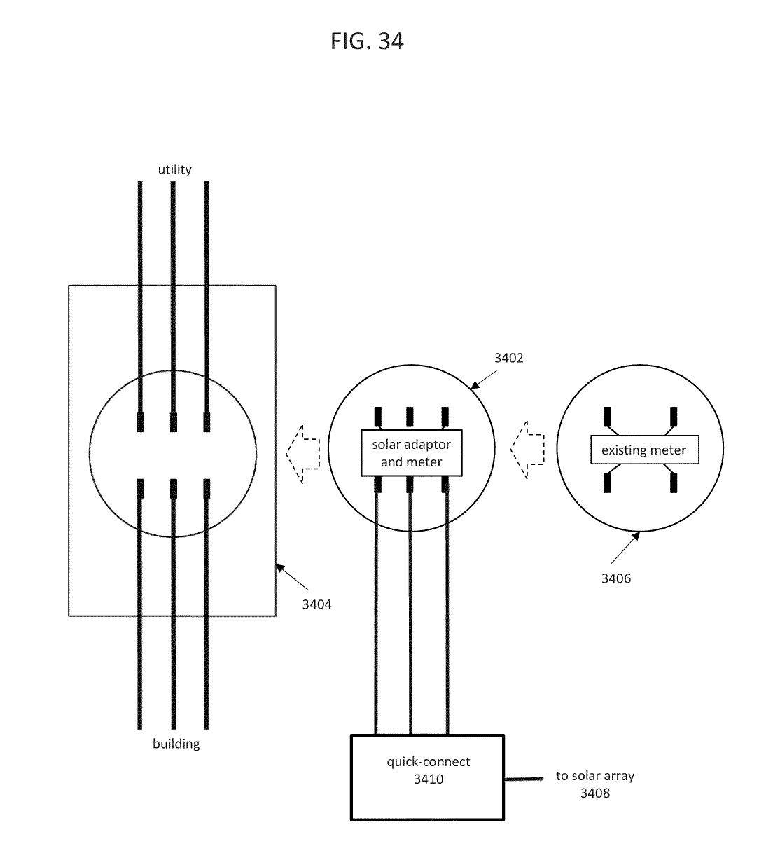

FIG. 34 schematically depicts the system 3300 of FIG. 33. A pre-wired solar adaptor 3402, including a solar meter component, is connected to the building meter box 3404 as a pass-through that mounts between meter socket in building meter box 3404 and building net meter 3406 and connects a solar array 3408 in parallel with the building electrical system. The physical mounting of adaptor 3402 completes electrical connections between meter box 3404 and meter 3406, hence the designation of adaptor 3402 as a pass-through adaptor. Adaptor 3402 is connected to solar array 3408 by quick-connect 3410. Other safety devices such as breakers, fuses, or disconnects may be internal to the solar meter adaptor 3402 or quick connect 3410, allowing direct connection of the solar array via multi-conductor electrical cable to the quick connector electrical adaptor 3410. By using this type of quick connection at the building meter box 3404, installation time and cost may be reduced as compared with installations that require more wiring steps or require entry of the building and use of the internal building utility panel and breaker box. In other embodiments, this type of meter and adaptor arrangement may be used with other power generation systems such as wind, natural gas generators, fuel cells, micro-hydroelectric generators, and others.

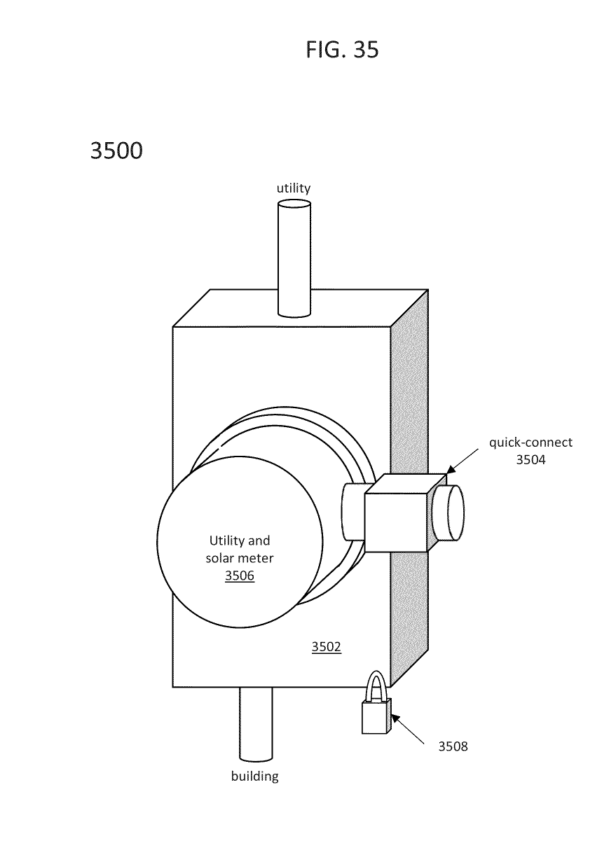

FIG. 35 depicts an illustrative pre-wired electrical system 3500 for interfacing a solar array with building electrical mains. A solar array (not shown) is connected to building meter box 3502 by means of Quick-connect electrical connector 3504, which communicates with solar and utility meter 3506. Solar and utility meter 3506 is a pre-wired meter that combines standard energy-use net metering with solar-generation metering. Solar meter 3506 replaces an existing building meter in meter socket of building meter box 3502. System 3500 is secured by standard utility safety protections, including tamper-proof tag 3508. Other safety devices such as breakers, fuses, disconnects may be internal to the solar and utility meter adaptor 3506 or quick connect 3504, allowing direct connection of the solar array via multi-conductor electrical cable to the quick connector electrical adaptor 3504. By using this type of quick connection at the building meter box 3502, installation time and cost may be reduced as compared with installations that require more wiring steps or require entry of the building and use of the internal building utility panel and breaker box. In other embodiments, this type of meter and adaptor arrangement may be used with other power generation systems such as wind, natural gas generators, fuel cells, micro-hydroelectric generators, and others.

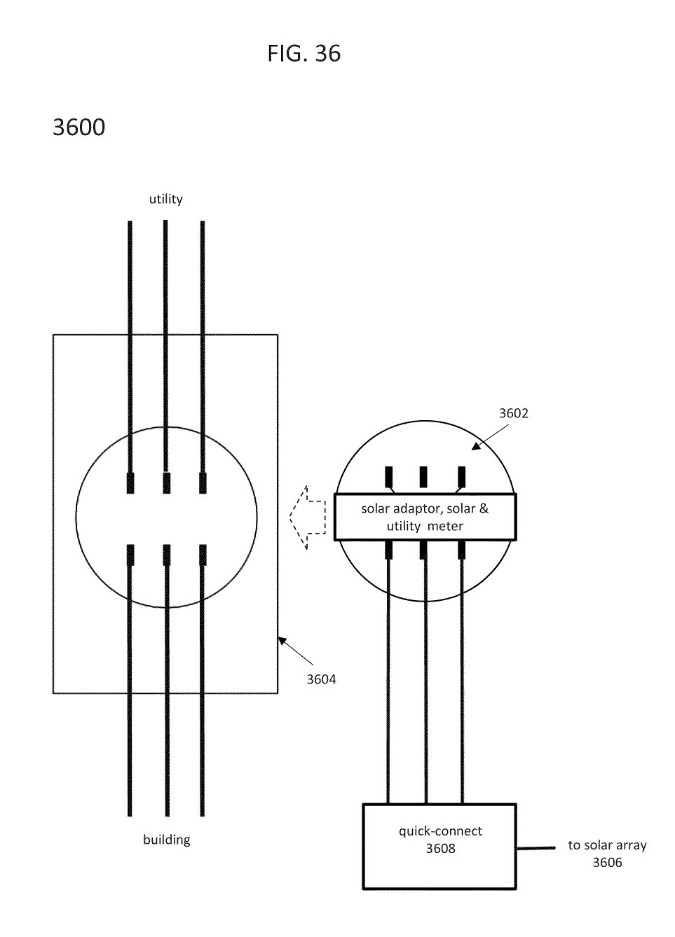

FIG. 36 schematically depicts the system 3500 of FIG. 35. A pre-wired solar meter 3602, including solar generation meter and standard net meter components, is connected to the building meter box 3604 by replacing existing building meter in the meter socket of building meter box 3604. Solar meter 3602 is connected to solar array 3606 by a Quick Connect connector at 3608. In other embodiments, this type of meter and adaptor arrangement may be used with other power generation systems such as wind, natural gas generators, fuel cells, micro-hydroelectric generators, and others.

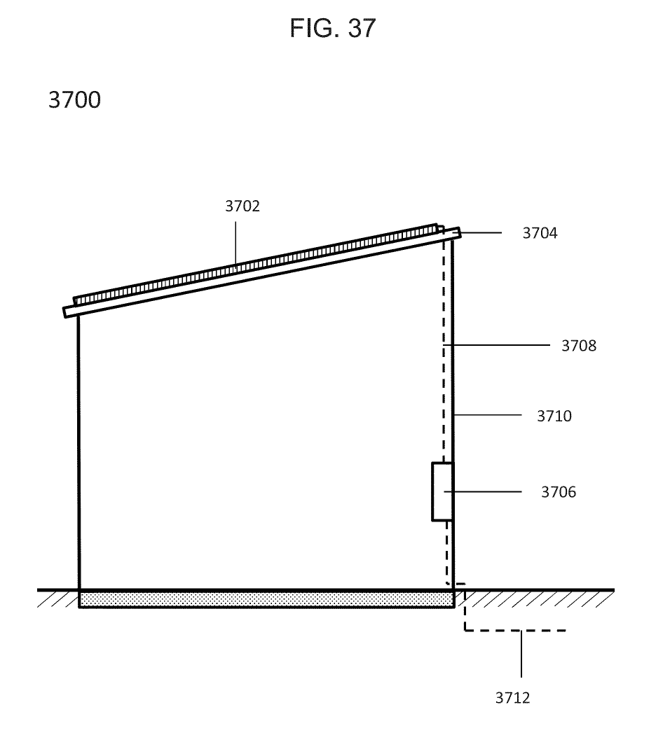

FIG. 37 is a schematic cross-sectional depiction of an illustrative installation of an EZPV meta-module 3702 on a small building (e.g., shed) having a sloping roof 3704. In one embodiment, the EZPV meta-module and small building are pre-assembled as a unit. Pre-assembled unit has a width of less than 8.5′ to allow transportation by truck. The unit may be pre-wired for lighting and electrical outlets with a single required electrical connection to connect both the lighting and electrical outlets in the building and the solar array to the electrical grid. In another embodiment, the small building is designed to come in sections that are readily assembled at the generation location. In one embodiment, the roof of the small building and the EZPV meta-module are preassembled. In one embodiment, the orientation of the roof 3704 is preferably approximately south-facing, so that the efficiency of the EZPV meta-module 3702 may not be excessively impaired by seasonal movement of the Sun to excessively grazing angles with respect to the surface of the meta-module 3702. The EZPV meta-module 3702 is connected to an electrical box that comprises a solar interconnection box 3706 (e.g., an assembly similar to assembly 2900A of FIG. 29A or assembly 2900B of FIG. 29B) by electrical wiring 3708 attached to a wall 3710. Electrical box also contains pre-wired wiring for lighting and electrical outlets (not shown). The solar interconnection box 3706 is connected by electrical wiring 3712, which may be housed in a trench and which leads to a standard consumer utility meter (not shown). The delivery and electrical connection of this entire building may take place in a short amount of time, such as less than one hour, less than two hours, or less than four hours.

In another embodiment, the pre-fabricated free standing building with pre-assembled solar meta-module is greater than 8.5′ wide buildings but may still be transported by truck as an oversized load.

Under optimal illumination conditions, one square meter of the Earth's surface is illuminated with a maximum solar illumination of slightly more than 1 kiloWatt of radiant power. Using the best semiconductor multijunction solar cells available today that are designed to operate with unconcentrated sunlight, more than 30 and less than 40 percent efficiency of conversion of light energy to electrical power is possible. With more conventional crystalline silicon solar cells, the record for one sun conversion is about 25 percent efficiency. For commercial crystalline silicon solar cells, the efficiency ranges from about 10 to 20 percent. For amorphous silicon solar cells, the one sun conversion efficiency is below 10 percent. Therefore, a 10 Watt output from a single solar cell of any of the above enumerated types would require a single cell having an illuminated surface area as given in the table below, assuming illumination with 1 kiloWatt of radiant power per square meter, which is equal to 10 Watts per 1/100^{th} of a square meter, or 10 Watts per 100 square centimeters (10 Watts per 15.5 square inches, at 2.54 centimeters per inch).

| | Illumination | Power | | |
|---|---|---|---|---|
| | per | per 100 | Area for 10 | Area for 10 |
| Efficiency | 100 square | square | Watts output | Watts output |
| (percent) | centimeters | centimeters | power (cm²) | power (inch²) |
| 40 | 10 Watts | 4 Watts | 250 | 38.75 |
| 30 | 10 Watts | 3 Watts | 333.33 | 51.67 |
| 20 | 10 Watts | 2 Watts | 500 | 77.50 |
| 10 | 10 Watts | 1 Watt | 1000 | 155.00 |
| 5 | 10 Watts | 0.5 Watt | 2000 | 310.00 |

Given that the largest single cells of each efficiency level produced to date are considerably smaller than the corresponding size needed to achieve an electrical output of 10 Watts, it is safe to say that with today's technology, no single nonconcentrator solar cell reaches an electrical output of 10 Watts.

A photovoltaic module consists of an array of photovoltaic cells wired in series and parallel and enclosed in a weather-resistance frame, typically with a glass cover and two electrical power connectors. Photovoltaic modules are sized to be carried by a single worker and typically have a power level of more than 50 Watts and less than 500 Watts. The illuminable area of a photovoltaic module is typically less than 32 square feet.

In various embodiments, the meta-module or prefabricated array of photovoltaic modules according to the invention is configured to generate a respective one of 500 Watts, 1 kiloWatt, 2 kiloWatt, 4 kiloWatts or more under illumination with 1 kiloWatt of radiant power per square meter.

In various embodiments, the meta-module or prefabricated array of photovoltaic modules is configured to have an illuminable area of respective one of 32 square feet, 64 square feet, 128 square feet, or more.

In various embodiments, the meta-module or prefabricated array of photovoltaic modules may be larger than can reasonably be carried by a single worker in a safe fashion and may require lifting by a lifting mechanism.

### DEFINITIONS

Herein, the term “light” includes but is not restricted to the visible portion of the electromagnetic spectrum.

As used herein, the terms “wire,” “wiring” and the like refer to one or more conductors that are rated to carry power or information between two points. Thus, the singular term should be taken to include a plurality of parallel conductors where appropriate.

As used herein, the phrases “electrical connection,” “electrically connected,” “making an electrical connection” and the like are intended to denote either electrical connections between two objects or devices that can be direct electrical connections (e.g., an electrical conductor of the first device is directly connected to an electrical conductor of the second device, such as plugging a household electrical appliance into a wall socket) or electrical connections between two objects or devices that can be completed through the intermediation of a third electrical device (e.g., plugging the appliance into an extension cord that is then plugged into a wall socket). By way of further example, in the prefabricated arrays of photovoltaic modules described herein, modules may be in series or in parallel, so that in some embodiments, an electrical terminal of a module may not be in direct connection to an electrical terminal of a frame but rather may be connected by the intermediation of another module to the electrical terminal of the frame. In either case, the phrase “electrically connected” would be appropriate.

As used herein, the inventive concept related to attaching an array of photovoltaic modules to a frame in a prefabricated fashion is not limited to a particular linguistic description and may be described at least as a meta-module, an array of modules, a modular prefabricated PV system, or a prefabricated array of photovoltaic modules.

Unless otherwise explicitly recited herein, any reference to an electronic signal or an electromagnetic signal (or their equivalents) is to be understood as referring to a non-transitory electronic signal or a non-transitory electromagnetic signal.

### Theoretical Discussion

Although the theoretical description given herein is thought to be correct, the operation of the devices described and claimed herein does not depend upon the accuracy or validity of the theoretical description. That is, later theoretical developments that may explain the observed results on a basis different from the theory presented herein will not detract from the inventions described herein.

Any patent, patent application, patent application publication, journal article, book, published paper, or other publicly available material identified in the specification is hereby incorporated by reference herein in its entirety. Any material, or portion thereof, that is said to be incorporated by reference herein, but which conflicts with existing definitions, statements, or other disclosure material explicitly set forth herein is only incorporated to the extent that no conflict arises between that incorporated material and the present disclosure material. In the event of a conflict, the conflict is to be resolved in favor of the present disclosure as the preferred disclosure.

While the present invention has been particularly shown and described with reference to the preferred mode as illustrated in the drawing, it will be understood by one skilled in the art that various changes in detail may be affected therein without departing from the spirit and scope of the invention as defined by the claims.

What is claimed is:

1. A method of installing a prefabricated array of photovoltaic modules, comprising the steps of:
providing at an installation location a prefabricated array of photovoltaic modules, said prefabricated array of photovoltaic modules having a frame with a plurality of photovoltaic modules mechanically connected to said frame, each of said plurality of photovoltaic modules comprising one or more photovoltaic solar cells, each of said plurality of photovoltaic modules configured to generate at least 50 Watts of electrical power under an illumination level of 1 kiloWatt per square meter, said prefabricated array of photovoltaic modules having an electrical connector mechanically connected to said frame and configured to provide electrical power output terminals, said prefabricated array of photovoltaic modules configured to be transported from a first location different from said installation location, with an electrical connection to said prefabricated array of photovoltaic modules to be made at said installation location by way of said electrical connector;
disposing said prefabricated array of photovoltaic modules in a working orientation at said installation location; and
making an electrical connection between said prefabricated array of photovoltaic modules and an electrical load by way of said electrical connector, thereby making said prefabricated array of photovoltaic modules electrically operational when said prefabricated array of photovoltaic modules is illuminated.

2. The method of installing a prefabricated array of photovoltaic modules of claim 1, wherein said steps of disposing said prefabricated array of photovoltaic modules in a working orientation and making an electrical connection between said prefabricated array of photovoltaic modules and an electrical load by way of said electrical connector so as to make said prefabricated array of photovoltaic modules electrically operational when said prefabricated array of photovoltaic modules is illuminated are completed in a period of eight hours or less, measured from a time when said prefabricated array of photovoltaic modules first arrives at said installation location.

3. The method of installing a prefabricated array of photovoltaic modules of claim 2, wherein said period is four hours or less, measured from a time when said prefabricated array of photovoltaic modules first arrives at said installation location.

4. The method of installing a prefabricated array of photovoltaic modules of claim 2, wherein said period is two hours or less, measured from a time when said prefabricated array of photovoltaic modules first arrives at said installation location.

5. The method of installing a prefabricated array of photovoltaic modules of claim 2, wherein said period is one hour or less, measured from a time when said prefabricated array of photovoltaic modules first arrives at said installation location.

6. The method of installing a prefabricated array of photovoltaic modules of claim 1, further comprising the step of lifting said prefabricated array of photovoltaic modules by way of a lifting point mechanically connected to said frame.

7. The method of installing a prefabricated array of photovoltaic modules of claim 6, wherein said lifting point mechanically connected to said frame is configured to allow said prefabricated array of photovoltaic modules to be lifted by a mechanical lifting apparatus.

8. The method of installing a prefabricated array of photovoltaic modules of claim 1, further comprising the step of securely attaching said prefabricated array of photovoltaic modules to said installation location using an attachment point mechanically connected to said frame.

9. The method of installing a prefabricated array of photovoltaic modules of claim 8, wherein said attachment point mechanically connected to said frame is mechanically connected to a corresponding attachment point installed at said installation location.

10. The method of installing a prefabricated array of photovoltaic modules of claim 9, wherein said attachment point mechanically connected to said frame is mechanically connected to said corresponding attachment point in a readily detachable fashion.

11. The method of installing a prefabricated array of photovoltaic modules of claim 1, further comprising the step of installing an inverter between said prefabricated array of photovoltaic modules and said electrical load.

12. The method of installing a prefabricated array of photovoltaic modules of claim 1, wherein said prefabricated array of photovoltaic modules further comprises a mechanical counterweight configured to counterbalance a mass of said prefabricated array of photovoltaic modules.

13. The method of installing a prefabricated array of photovoltaic modules of claim 12, wherein said prefabricated array of photovoltaic modules is installed at a ridge of a peaked roof.

14. The method of installing a prefabricated array of photovoltaic modules of claim 1, wherein said prefabricated array of photovoltaic modules further comprises a removable exoskeleton configured to stabilize said prefabricated array of photovoltaic modules during a time when said prefabricated array of photovoltaic modules is moved to said installation location.

15. The method of installing a prefabricated array of photovoltaic modules of claim 1, wherein said prefabricated array of photovoltaic modules is configured to provide 1 kiloWatt or more of electrical power under an illumination level of 1 kiloWatt per square meter.

16. The method of installing a prefabricated array of photovoltaic modules of claim 1, wherein an illuminable area of said prefabricated array of photovoltaic modules is at least 64 square feet.

17. The method of installing a prefabricated array of photovoltaic modules of claim 1, wherein at least one module of said plurality of photovoltaic modules has at least one of a ground terminal in electrical contact with said ground terminal of said frame by way of a ground terminal of a second module of said plurality of photovoltaic modules, a first electrical power terminal in electrical contact with said first electrical power terminal of said frame by way of a first electrical power terminal of a second module of said plurality of photovoltaic modules, and a second electrical power terminal in electrical contact with said second electrical power terminal of said frame by way of a second electrical power terminal of a second module of said plurality of photovoltaic modules.

18. The method of installing a prefabricated array of photovoltaic modules of claim 1, wherein at least one module of said plurality of photovoltaic modules has at least one of a ground terminal in electrical contact with said ground terminal of said frame by way of an electrical connection provided by a first intermediate electrical device, a first electrical power terminal in electrical contact with said first electrical power terminal of said frame by way of an electrical connection provided by a second intermediate electrical device, and a second electrical power terminal in electrical contact with said second electrical power terminal of said frame by way of an electrical connection provided by a third intermediate electrical device.

19. The prefabricated array of photovoltaic modules of claim 18, wherein at least two of said first intermediate electrical device, said second intermediate electrical device, and said third intermediate electrical device are the same.

20. The method of installing a prefabricated array of photovoltaic modules of claim 1, wherein said prefabricated array of photovoltaic modules includes a power inverter integrated with said prefabricated array of photovoltaic modules.

21. The method of installing a prefabricated array of photovoltaic modules of claim 1, wherein each of said prefabricated array of photovoltaic modules includes a power inverter integrated therewith.

22. The method of installing a prefabricated array of photovoltaic modules of claim 1, wherein said electrical connector is a disconnectable connector.
